(19) United States
(12) Patent Application Publication
(10) Pub. No.: US 2025/0006741 A1
(43) Pub. Date: Jan. 2, 2025

(54) INTEGRATED CIRCUIT DEVICE AND MANUFACTURING METHOD THEREOF

(71) Applicant: TAIWAN SEMICONDUCTOR MANUFACTURING COMPANY, LTD., Hsinchu (TW)

(72) Inventors: Chun-Hsuan WANG, Hsinchu County (TW); Wei-Cheng LIN, Taichung City (TW); Jiann-Tyng TZENG, Hsinchu City (TW)

(73) Assignee: TAIWAN SEMICONDUCTOR MANUFACTURING COMPANY, LTD., Hsinchu (TW)

(21) Appl. No.: 18/345,552

(22) Filed: Jun. 30, 2023

(51) Int. Cl. H01L 27/12; H01L 21/84

(52) U.S. Cl. CPC H01L 27/12; H01L 21/84; H01L 21/8221

(57) ABSTRACT

An integrated circuit device includes a first semiconductor layer, a second semiconductor layer, a first source/drain epitaxial structure, a second source/drain epitaxial structure, and a first contact plug. The second semiconductor layer is above the first semiconductor layer. The first and second semiconductor layers are vertically spaced apart from each other. The first source/drain epitaxial structure is on a side of the first semiconductor layer. The second source/drain epitaxial structure is on a side of the second semiconductor layer and above the first source/drain epitaxial structure. The first source/drain epitaxial structure has a portion extending beyond a sidewall of the second source/drain epitaxial structure from a top view. The first contact plug is over a frontside of the first source/drain epitaxial structure. The first contact plug overlaps the portion of the first source/drain epitaxial structure from the top view.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET structure in accordance with some embodiments of the present disclosure.

FIGS. 2A-9C illustrate schematic views of intermediate stages in the manufacture of an integrated circuit device in accordance with some embodiments of the present disclosure.

FIGS. 10A-13B illustrate schematic views of intermediate stages in the manufacture of an integrated circuit device in accordance with some embodiments of the present disclosure.

FIGS. 14A-18B illustrate schematic views of intermediate stages in the manufacture of an integrated circuit device in accordance with some embodiments of the present disclosure.

FIG. 19 is a schematic cross-sectional view of an integrated circuit device in accordance with some embodiments of the present disclosure.

FIG. 20 is a schematic cross-sectional view of an integrated circuit device in accordance with some embodiments of the present disclosure.

FIG. 21 is a schematic cross-sectional view of an integrated circuit device in accordance with some embodiments of the present disclosure.

FIG. 22 is a schematic cross-sectional view of an integrated circuit device in accordance with some embodiments of the present disclosure.

FIG. 23A is a schematic top view of an integrated circuit device in accordance with some embodiments of the present disclosure.

FIG. 23B is a schematic view of an integrated circuit device in FIG. 23A.

FIG. 24 is a schematic top view of an integrated circuit device in accordance with some embodiments of the present disclosure.

FIG. 25A is a schematic top view of an integrated circuit device in accordance with some embodiments of the present disclosure.

FIG. 25B is a schematic cross-sectional view of the integrated circuit device in FIG. 25A.

FIG. 26 is a schematic top view of an integrated circuit device in accordance with some embodiments of the present disclosure.

FIG. 27A is a schematic top view of an integrated circuit device in accordance with some embodiments of the present disclosure.

FIG. 27B is a schematic cross-sectional view of the integrated circuit device in FIG. 27A.

FIG. 28A is a circuit diagram of a AND-OR-INVERT-22 (AOI22) logic gate in accordance with some embodiments of the present disclosure.

FIGS. 28B and 28C are layouts of the AOI logic gate of FIG. 28A in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a GAA transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents. Stacked transistor structures, such as complementary field effect transistors (CFETs) including vertically stacked p-type FETs and n-type FETs, can provide further reduced footprint and density improvement for advanced IC technology nodes.

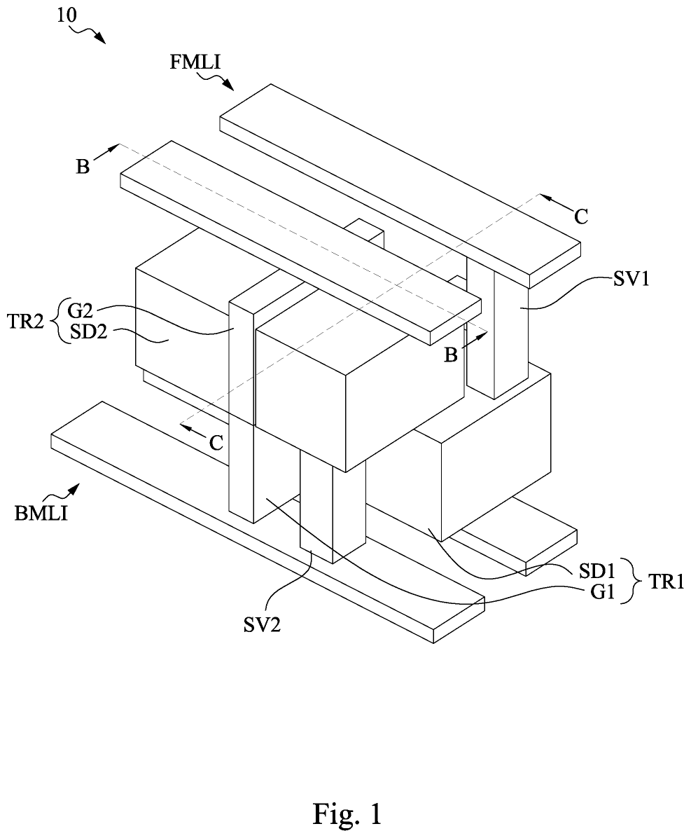

FIG. 1 is a perspective view of an example CFET structure in accordance with some embodiments of the present disclosure. In some embodiments of the present disclosure, a CFET structure 10 includes a first transistor TR1 and a second transistor TR2 vertically stacked over the first transistor TR1, and thus the second transistor TR2 can be interchangeably referred to as a top transistor and the first transistor TR1 can be interchangeably referred to as a bottom transistor. In some embodiments, the first transistor TR1 and the second transistor TR2 are GAA FET transistors. The first transistor TR1 includes first semiconductor channel layers disposed one above another, a first gate structure G1 wrapping around each of the first semiconductor channel layers, and first source/drain epitaxy structures SD1 on opposite sides of each of the first semiconductor channel layers. The second transistor TR2 includes second semiconductor channel layers vertically stacked one above another, a second metal gate structure G2 wrapping around each of the second semiconductor channel layers, and second source/drain epitaxy structures SD2 on opposite sides of each of the second semiconductor channel layers. The second source/drain epitaxy structures SD2 is non-aligned with the first source/drain epitaxy structures SD1. A shortened deep via SV1 may connect a frontside of the second source/drain epitaxy structures SD1 to metals of a front-side MLI structure FMLI. A shortened deep via SV2 may connect a backside of the second source/drain epitaxy structures SD2 to metals of a back-side MLI structure BMLI. In some embodiments, the second gate structure G2 can be electrically isolated from first gate structure G1 by dielectric bonding materials (not shown), as will be described in greater detail below. In some embodiments, the first transistor TR1 has a first conductivity type (e.g., n-type) and the second transistor TR2 has a second conductivity type (e.g., p-type) different from the first conductivity type.

FIG. 1 further illustrates reference cross-sections that are used in later figures. Cross-section B-B is parallel to the direction of current flow between the epitaxial source/drain structures SD1 of the bottom transistor TR1 and the direction of current flow between the epitaxial source/drain structures SD2 of the top transistor TR2. Cross-section C-C is perpendicular to the cross-section B-B and extends through epitaxial source/drain structures SD1 of the bottom transistor TR1 and epitaxial source/drain structures SD2 of the top transistor TR2. Subsequent figures refer to these reference cross-sections for clarity.

The stack configuration of n-type and p-type transistors of CFET may scale cell area. However, a major challenge associated with CFET is the connection between CFET and the front-side/back-side MLI structures. For example, a deep via is formed to extend from a front-side MLI structure to an epitaxial structure of a bottom transistor, and/or a deep via is formed to extend from a back-side MLI structure to an epitaxial structure of a top transistor. The formation of the deep vias is challenging because of their high aspect ratio (high ratio of depth to width). Moreover, the deep vias may occupy cell area, which may increase cell height. Furthermore, due to the difference of carrier mobility between n-type and p-type transistors, CFET with same-sized epitaxial structures for n-type and p-type transistors may provide less effective current. Furthermore, in front-side I/O pin cases, the bottom transistors with longer distance and large resistance may suffer speed degradation, which may cause imbalanced performance between n-type and p-type transistors.

The present disclosure, in various embodiments, provides a solution to the aforementioned challenges by forming non-aligned source/drain epitaxial structures. The non-aligned source/drain epitaxial structures creates space for shortened deep via connecting the source/drain epitaxial structures to the frontside/backside metal with less cell height. The shortened deep via extends from a front-side MLI structure to a frontside of an epitaxial structure of a bottom transistor, and/or the shortened deep via extends from a back-side MLI structure to a backside of an epitaxial structure of a top transistor. Such a configuration can reduce the challenge of via formation due to lower aspect ratio of vias. The non-aligned source/drain epitaxial structures may compensate the difference of carrier mobility between n-type and p-type transistors by tuning the sizes thereof, such that the CFET may provide a greater effective current. Furthermore, the non-aligned source/drain epitaxial structures and the shortened deep via with less distance and smaller resistance may balance the performance between the n-type and p-type transistors, thereby increasing the effective current to be provided.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

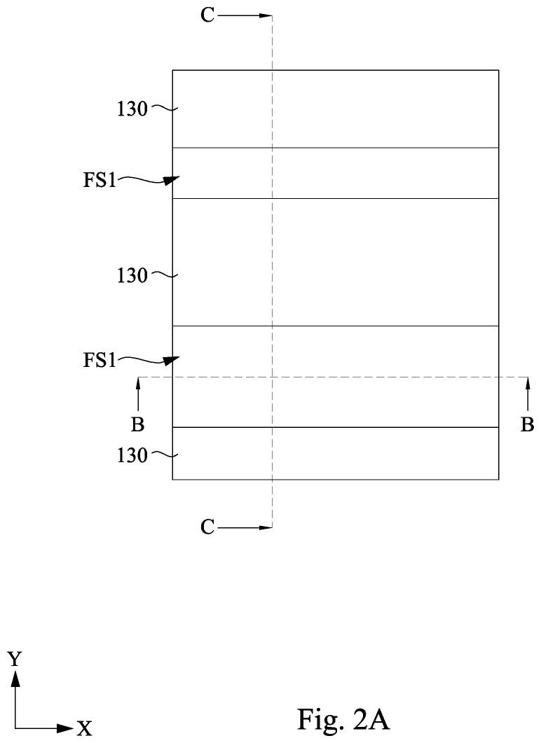

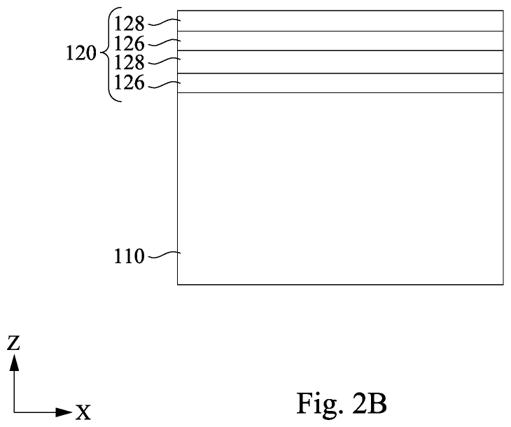

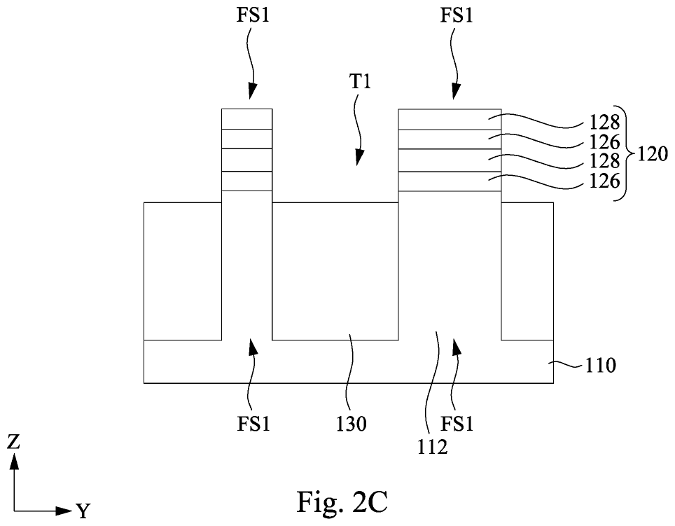

FIGS. 2A-9C illustrate schematic views of intermediate stages in the manufacture of an integrated circuit device in accordance with some embodiments of the present disclosure. FIGS. 2A, 3A, 4A, 5A, 6A, 7A, 8A, and 9A are top views of the integrated circuit device at various manufacturing stages in accordance with some embodiments. FIGS. 2B, 3B, 4B, 5B, 6B, 7B, 8B, and 9B are cross-sectional views of the integrated circuit device (e.g., taken along line B-B in FIGS. 2A, 3A, 4A, 5A, 6A, 7A, 8A, and 9A) at various manufacturing stages in accordance with some embodiments. FIGS. 2C, 3C, 4C, 5C, 6C, 7C, 8C, and 9C are cross-sectional views of the integrated circuit device (e.g., taken along line C-C in FIGS. 2A, 3A, 4A, 5A, 6A, 7A, 8A, and 9A) at various manufacturing stages in accordance with some embodiments. It is understood that additional steps may be provided before, during, and after the steps shown in FIGS. 2A-9C, and some of the steps described below can be replaced or eliminated for additional embodiments of the method. The order of the operations/processes may be interchangeable.

Reference is made to FIGS. 2A-2C. An epitaxial stack 120 is formed over a substrate 110, and patterned into fins FS1. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes sacrificial layers 126, and channel layer 228 stacked in a sequence over the substrate 110. In some embodiments, the layers 126 and 128 may include SiGe with various semiconductor compositions. For example, a Si concentration in the sacrificial layers 126 is less than a Si concentration in the channel layers 128. Stated differently, in some embodiments, a Ge concentration in the sacrificial layers 126 is greater than a Ge concentration in the channel layers 128. For example, the channel layers 128 are SiₓGe₁₋ₓ, the sacrificial layers 126 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 126 include SiGe and the channel layers 128 include Si, the Si oxidation rate of the channel layers 128 is less than the SiGe oxidation rate of the sacrificial layers 126.

The channel layers 128 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 128 may be referred to as semiconductor channels in the context.

By way of example, epitaxial growth of the layers 126 and 128 of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the layers 126 and 128, include suitable semiconductor material, such as like Si, Ge, Sn, SiGe, GeSn, III-V semiconductor, the like, or the combination thereof. In some embodiments, the channel layers 128 may include a same semiconductor material as that substrate 110. In some embodiments, the epitaxially grown sacrificial layers 126 include a different material than the substrate 110. In some other embodiments, at least one of the layers 126 and 128 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the layers 126 and 128 may be chosen based on providing differing oxidation and/or etching selectivity properties. In some embodiments, the layers 126 and 128 are intrinsic semiconductor layers, which are not intentionally doped, for example, not having intentionally placed dopants, but rather having a doping resulting from process contaminants. In some embodiments, the layers 126 and 128 are substantially dopant-free (i.e., having an extrinsic dopant concentration from about 0 cm⁻³ to about 1×10¹⁸ cm⁻³), where for example, no intentional doping is performed during the epitaxial growth process.

A plurality of semiconductor fins FS1 extending from the substrate 110 are formed. The semiconductor fins FS1 may extend substantially along a direction X. In various embodiments, each of the fins FS1 includes a substrate portion 112 formed from the substrate 110 and portions of each of the epitaxial layers of the epitaxial stack 120 including epitaxial layers 126 and 128. In some embodiments, one of the fins FS1 may be wider than another one of the fins FS1 such that a size of a source/drain feature epitaxially grown one said one of the fins FS1 is greater than a size of a source/drain feature epitaxially grown one said another one of the fins FS1 in a later fabrication stage. The fins FS1 may be fabricated using suitable processes including photolithography and etch processes. The photolithography process may include forming a photoresist layer (not shown) over a hard mask layer over the stack 120, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions through the hard mask layer, through the epitaxial stack 120, and into the substrate 110, thereby leaving the plurality of extending fins FS1. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS1.

The fins FS1 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS1 by etching initial epitaxial stack 120. The etching process can include dry etching, wet etching, reactive ion etching (RIE), and/or other suitable processes.

Isolation structures 130 are formed in the trench T1 between the fins FS1. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material over the fins FS1, followed by an etching back process. Through the etching back process, a top surface of the isolation structure 130 is lowered to a position lower than a bottommost surface of the layers 126 and 128, such that the sacrificial layers 126 and the channel layers 128 are exposed.

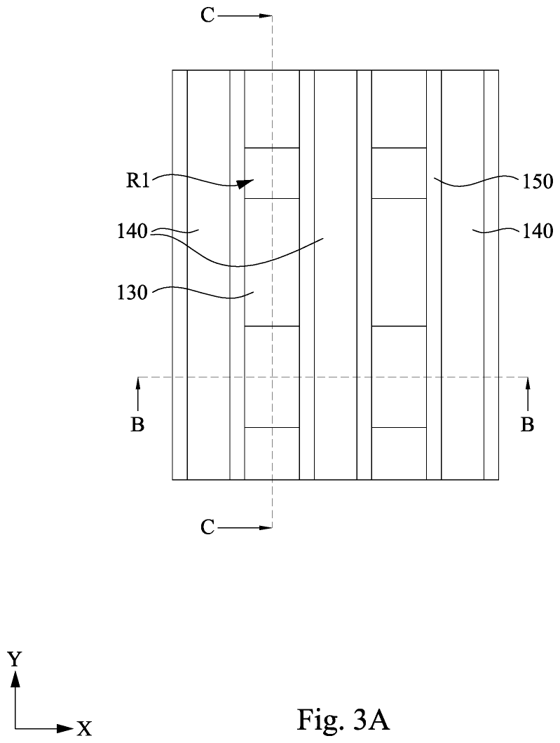

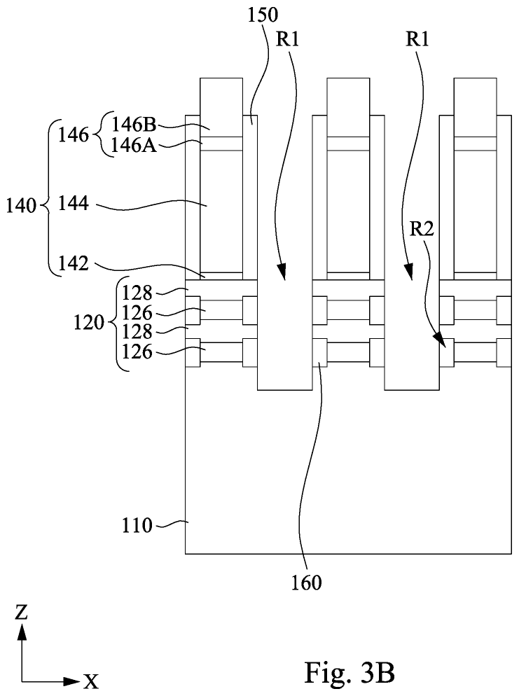

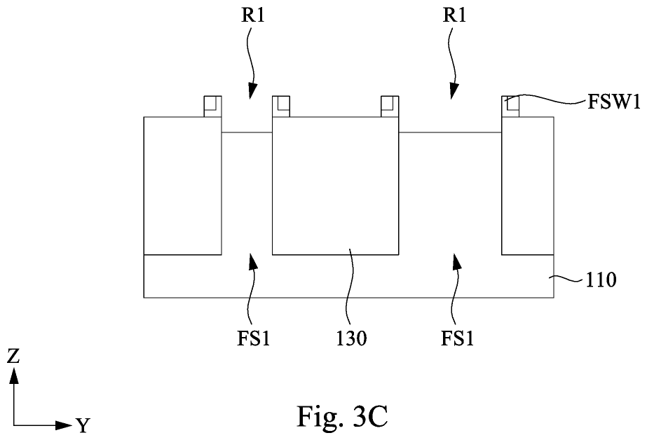

Reference is made to FIGS. 3A-3C. One or more dummy gate structures 140 are formed on the epitaxial stack 120. The dummy gate structure 140 may include a gate dielectric 142, a gate electrode 144, and a hard mask 146. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a CVD process, a sub-atmospheric CVD (SACVD) process, a FCVD process, an ALD process, a PVD process, or other suitable process. The gate electrode 144 may include polycrystalline silicon (polysilicon). The hard mask 146 may include a silicon oxide layer 146A and a silicon nitride layer 146B over the silicon oxide layer 146A. In some embodiments, the materials of the dummy gate structures 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS1 are partially exposed on opposite sides of the dummy gate structure 140.

Gate spacers 150 are formed on opposite sidewalls of the dummy gate structures 140. The spacers 150 may be made of a dielectric material such as silicon oxide, silicon nitride, silicon carbide, silicon oxynitride, SiCN, silicon oxycarbide, SiOCN, and/or combinations thereof. In some embodiments, each of the spacers 150 includes a single layer or multiple layers. In some embodiments, fin sidewall spacers FSW1 are formed on opposite sides of the fins FS1. The fin sidewall spacers FSW1 may be made of a dielectric material such as silicon oxide, silicon nitride, silicon carbide, silicon oxynitride, SiCN, silicon oxycarbide, SiOCN, and/or combinations thereof. The gate spacers 150 or/and the fin sidewall spacers FSW1 may be formed by first depositing one or more conformal spacer material layers and subsequently etching back the one or more spacer material layers to form the gate spacers 150 or/and the fin sidewall spacers FSW1. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS1, leaving the gate spacers 150 or/and the fin sidewall spacers FSW1 on the vertical surfaces, such as the sidewalls of the dummy gate structures 140 and sidewalls of the fins FS1.

After formation of the dummy gate structures 140 and the gate spacers 150, exposed portions of the semiconductor fins FS1 that extend laterally beyond the gate spacers 150 (e.g., in source/drain regions of the fins FS1) are etched by using, for example, an anisotropic etching process that uses the dummy gate structures 140 and the gate spacers 150 as an etch mask, resulting in recesses R1 into the semiconductor fins FS1 and between corresponding dummy gate structures 140. After the anisotropic etching, end surfaces of the sacrificial layers 126 and the channel layers 128 are exposed by the recesses R1 and aligned with respective outermost sidewalls of the gate spacers 150, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. Through the etching process(es), top ends of the fin sidewall spacers FSW1 may be lowered to a position below tops of the fins FS1 (referring to FIG. 1C). In some alternatively embodiments, the fin sidewall spacers FSW1 are entirely removed by etching the recesses R1.

The sacrificial layers 126 are laterally or horizontally recessed by using suitable selective etching process, resulting in lateral/sidewall recesses R2 vertically between corresponding channel layers 128, and vertically between the channel layer 128 and the substrate portion 112. For example, end surfaces of the sacrificial layers 126 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The substrate portion 112 and the layers 128 may have a higher etch resistance to the selective etching process than that of the sacrificial layers 126. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 128 and the substrate portion 112 may not be not significantly etched by the process of laterally recessing the sacrificial layers 126. As a result, the layers 128 and the substrate portion 112 laterally extend past opposite end surfaces of the sacrificial layers 126.

Inner spacers 160 are formed in the recesses R2. Stated differently, the inner spacers 160 may be formed on opposite end surfaces of the laterally recessed sacrificial layers 126. The inner spacers 160 may include a low-k dielectric material, such as SiOₓ, SiON, SiOC, SiN, SiCN, or SiOCN. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 160 may include a single layer or multiple layers. The inner spacers 160 may serve to isolate metal gates from source/drain regions formed in subsequent processing. In the example of FIG. 3B, sidewalls of the inner spacers 160 are aligned with sidewalls of the channel layers 128.

The source/drain epitaxial structures 174 and 174′ are formed in the recess R1, and in contact with opposite sides of the channel layers 128. In some embodiments, the source/drain epitaxial structures 174 and 174′ may include Ge, Si, GaAs, AlGaAs, SiGe, GaAsP, SiP, or other suitable material. The source/drain epitaxial structures 174 and 174′ may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 174 and 174′ are not in-situ doped, an implantation process (i.e., a junction implant process) is performed to dope the source/drain epitaxial structures 174 and 174′. The source/drain epitaxial structures 174 and 174′ may be formed by performing an epitaxial growth process that provides an epitaxial material on the exposed surfaces of the channel layers 128 and the substrate 110. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 128 and the substrate 110.

In some embodiments of the present disclosure, the source/drain epitaxial structures 174 and 174′ are formed with different sizes/widths. For example, a width of the source/drain epitaxial structures 174′ are greater than a width of the source/drain epitaxial structures 174. The sizes/widths of the source/drain epitaxial structures 174 and 174′ can be tuned by deposition parameters in the epitaxial growth process.

After the formation of the source/drain epitaxial structures 174 or/and 174′, an etch stop layer (ESL) 182 and an interlayer dielectric (ILD) layer 184 are formed. In some examples, the ESL layer 182 includes a silicon nitride layer, silicon oxide layer, a silicon oxynitride layer, and/or other suitable materials. The ESL layer 182 may be formed by plasma-enhanced chemical vapor deposition (PECVD) process and/or other suitable deposition or oxidation processes. In some embodiments, the ILD layer 184 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 182. The ILD layer 184 may be deposited by a CVD process or other suitable deposition technique.

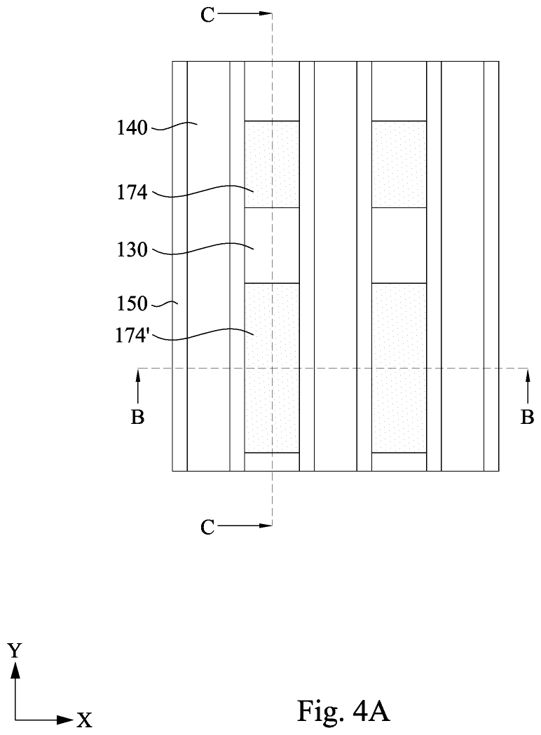

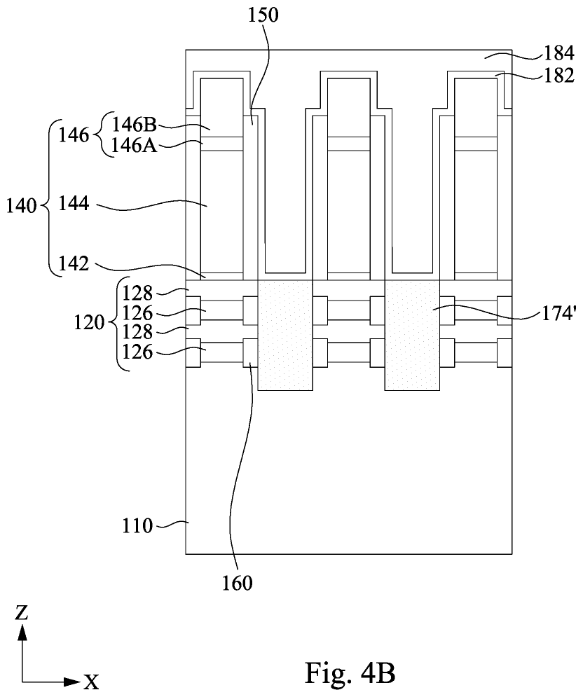

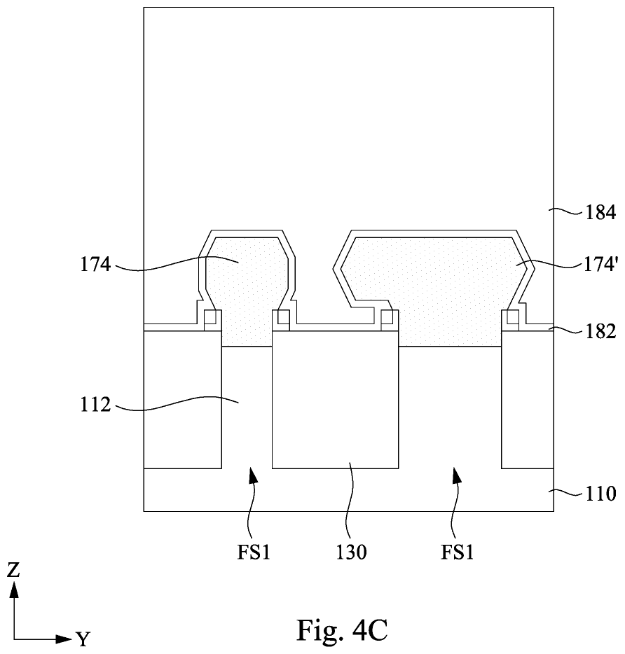

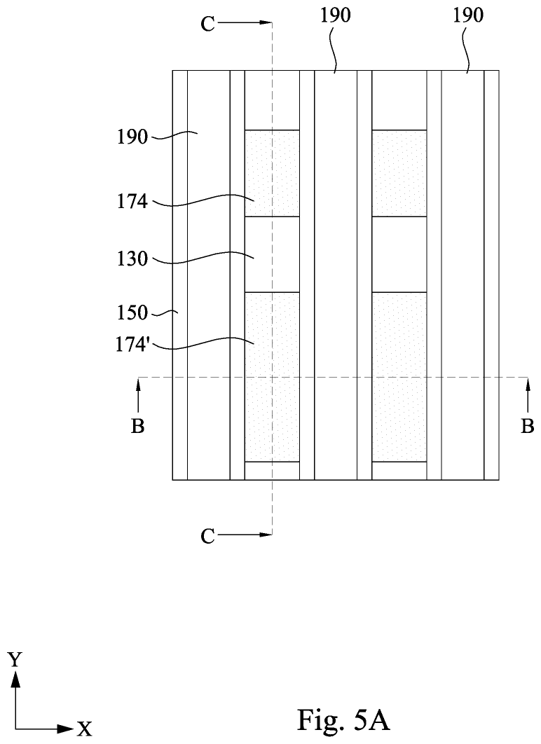

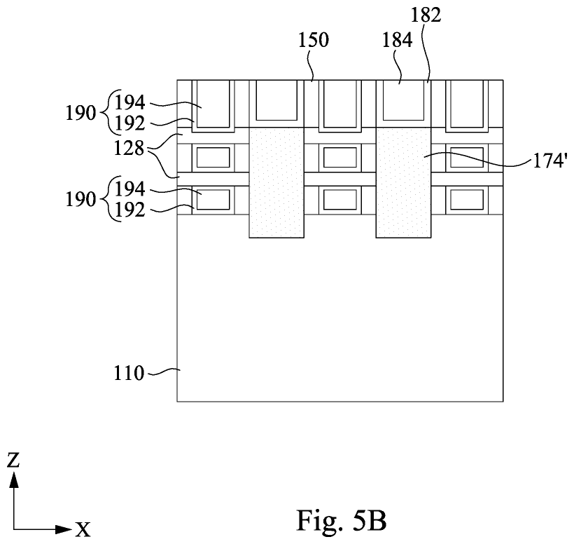

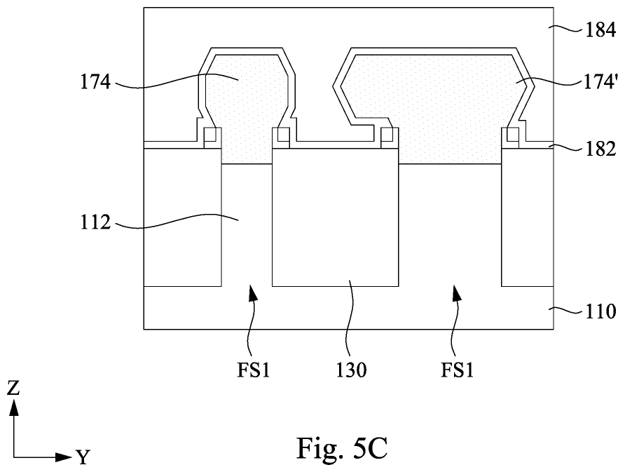

Reference is made to FIGS. 5A-5C. The dummy gate structure 140 and the sacrificial layer 126 (referring to FIGS. 4A and 4B) are replaced with a high-k/metal gate structure 190. The dummy gate structures 140 (referring to FIGS. 4A and 4B) are removed, followed by removing the sacrificial layers 126 (referring to FIG. 4B). For example, the dummy gate structures 140 (referring to FIGS. 4A and 4B) are removed by using a selective etching process (e.g., selective dry etching, selective wet etching, or a combination thereof) that etches the materials in dummy gate structures 140 (referring to FIGS. 4A and 4B) at a faster etch rate than it etches other materials (e.g., the gate spacers 150, the ESL layer 182, and/or the ILD layer 184), thus resulting in gate trenches between corresponding gate spacers 150, with the sacrificial layers 126 (referring to FIG. 4B) exposed in the gate trenches. Subsequently, the sacrificial layers 126 (referring to FIG. 4B) in the gate trenches are etched by using another selective etching process that etches the sacrificial layers 126 at a faster etch rate than it etches the layers 128 and the substrate portion 112, thus forming openings/spaces between neighboring layers 128 and the substrate portion 112. The openings/spaces may expose the sidewalls of the inner spacers 160. In this way, the channel layers 128 become nanosheets suspended over the substrate 110 and between the source/drain epitaxial structures 174/174′. This step is also called a channel release process. At this interim processing step, the openings/spaces surrounding the nanosheets 128 may be filled with ambient environment conditions (e.g., air, nitrogen, etc). In some embodiments, the nanosheets 128 can be interchangeably referred to as nanowires, nanoslabs and nanorings, depending on their geometry. For example, in some other embodiments, the channel layers 128 may be trimmed to have a substantial rounded shape (i.e., cylindrical) due to the selective etching process for completely removing the sacrificial layers 126 (referring to FIG. 4B). In that case, the resultant channel layers 128 can be called nanowires.

In some embodiments, the sacrificial layers 126 (referring to FIG. 4B) are removed by using a selective dry etching process. In some embodiments, the sacrificial layers 126 (referring to FIG. 4B) are SiGe and the channel layers 128 are silicon allowing for the selective removal of the sacrificial layers 126 (referring to FIG. 4B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 126 (referring to FIG. 4B) are removed. Moreover, because oxidation rate of Si is much lower (sometimes 30 times lower) than oxidation rate of SiGe, the channel layers 128 and the substrate portion 112 may remain substantially intact during the channel release process.

Replacement gate structures 190 are then respectively formed in the gate trenches to surround each of the nanosheets 128 suspended in the gate trenches. The gate structures 190 may be final gates of GAA FETs. The final gate structure may be a high-k/metal gate stack, however other compositions are possible. In some embodiments, each of the gate structures 190 forms the gate associated with the multi-channels provided by the plurality of nanosheets 128. For example, the high-k/metal gate structures 190 are formed within the openings/spaces provided by the release of nanosheets 128. The high-k/metal gate structures 190 may be between the layers 128 and the substrate portion 112 and surrounded by the inner spacers 160.

In various embodiments, the high-k/metal gate structure 190 includes a gate dielectric layer 192 formed around the nanosheets 128 and a gate metal layer 194 formed around the dielectric layer 192 and filling a remainder of the gate trenches. Formation of the high-k/metal gate structures 190 may include one or more deposition processes to form various gate materials, followed by a CMP processes to remove excessive gate materials, resulting in the high-k/metal gate structures 190 having top surfaces level with a top surface of the ILD layer 184. Thus, transistors (e.g., GAA FET) are formed, and the high-k/metal gate structure 190 surrounds each of the nanosheets 128, and thus is referred to as a gate of the transistors (e.g., GAA FET).

The gate dielectric layer 192 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the layers 128 and the substrate portion 112 exposed in the gate trenches are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 194 includes one or more metal layers. For example, the gate metal layer 194 may include one or more work function metal layers stacked one over another and a fill metal filling up a remainder of gate trenches. The one or more work function metal layers in the gate metal layer 194 provide a suitable work function for the high-k/metal gate structures 190. For an n-type GAA FET, the gate metal layer 194 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 194 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 194 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

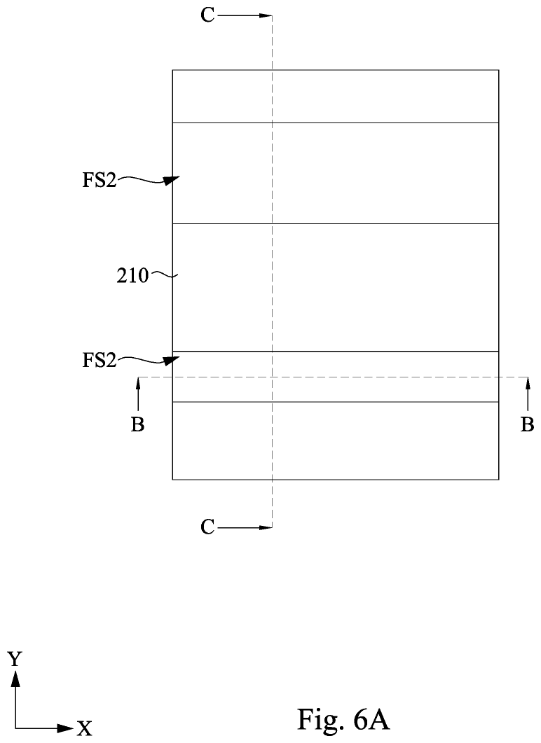

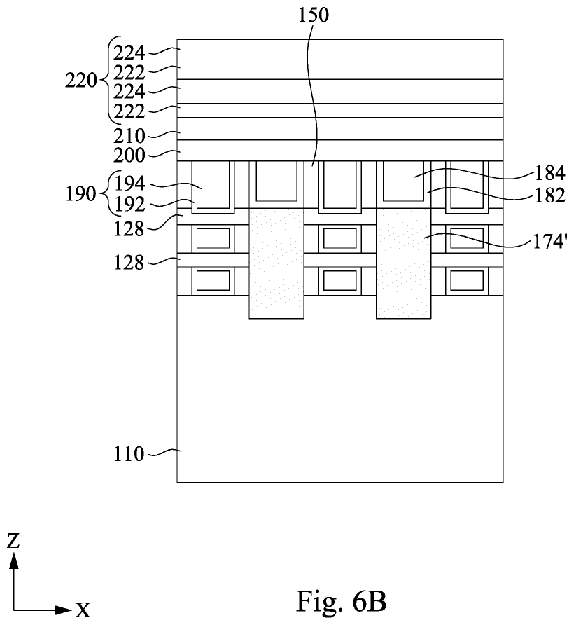

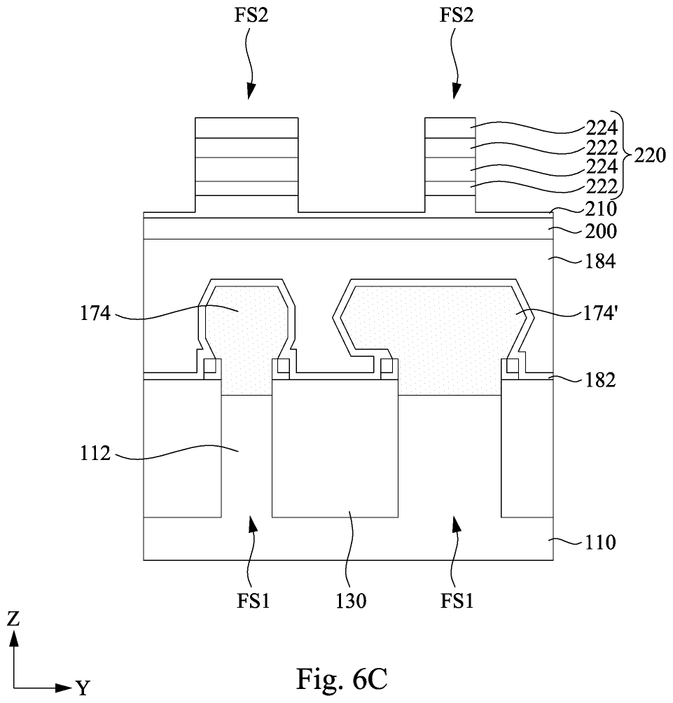

Reference is made to FIGS. 6A-6C. An epitaxial layer 220 is bonded over to the structure of FIGS. 5A-5C. Prior to the bonding process, a first dielectric layer 200 is deposited over the structure of FIGS. 5A-5C. In some embodiments, the first dielectric layer 200 includes silicon oxide, silicon nitride, silicon carbonitride, silicon oxycarbonitride, aluminum oxide, or hafnium oxide. As shown in FIG. 6B, the first dielectric layer 200 may be disposed on the ESL 182, the ILD layer 184, the gate structure 190, and the gate spacers 150. The first dielectric layer 200 may be referred to as a bonding layer or a passivation layer in some embodiments.

The epitaxial layer 220 is grown on another substrate, which may be similar to the substrate 110 and detailed description thereof is omitted for brevity. A second dielectric layer 210 is deposited over the epitaxial layer 220. In some embodiments, the second dielectric layer 210 includes silicon oxide, silicon nitride, silicon carbonitride, silicon oxycarbonitride, aluminum oxide, or hafnium oxide. The second dielectric layer 210 may be referred to as a bonding layer or a passivation layer in some embodiments. The epitaxial layer 220 includes sacrificial layers 222 and channel layers 224. The sacrificial layers 222 may have different semiconductor compositions from the channel layers 224. In some embodiments, the sacrificial layers 222 and the channel layers 224 may include SiGe with various semiconductor compositions. For example, a Si concentration in the sacrificial layers 222 is less than a Si concentration in the channel layers 224. Stated differently, in some embodiments, a Ge concentration in the sacrificial layers 222 is greater than a Ge concentration in the channel layers 224. For example, the channel layers 224 are SiₓGe₁₋ₓ, the sacrificial layers 222 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 222 include SiGe and the channel layers 224 include Si, the Si oxidation rate of the channel layers 224 is less than the SiGe oxidation rate of the sacrificial layers 222.

The channel layers 224 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 224 may be referred to as semiconductor channels in the context.

By way of example, epitaxial growth of the sacrificial layers 222 and the channel layers 224 of the stack 220 may be performed by a molecular beam epitaxy (MBE) process, a metalorganic chemical vapor deposition (MOCVD) process, and/or other suitable epitaxial growth processes. In some embodiments, the epitaxially grown layers such as, the layers 222 and 224, include suitable semiconductor material, such as like Si, Ge, Sn, SiGe, GeSn, III-V semiconductor, the like, or the combination thereof. In some embodiments, the layers 222 and 224 are intrinsic semiconductor layers, which are not intentionally doped, for example, not having intentionally placed dopants, but rather having a doping resulting from process contaminants. In some embodiments, the layers 222 and 224 are substantially dopant-free (i.e., having an extrinsic dopant concentration from about 0 cm⁻³ to about 1×10¹⁸ cm⁻³), where for example, no intentional doping is performed during the epitaxial growth process.

The epitaxial layer 220 is bonded to the structure of FIGS. 5A-5C by direct bonding or fusion bonding between the first dielectric layer 200 and the second dielectric layer 210. In an example direct bonding process, both the first dielectric layer 200 and the second dielectric layer 210 are cleaned, and the cleaned first dielectric layer 200 and second dielectric layer 210 are then mated and pressed together. The direct bonding may be strengthened by an anneal process. Although not explicitly shown in FIGS. 6A-6C, after the first dielectric layer 200 and the second dielectric layer 210 are bonded together, the substrate supporting the epitaxial layer 220 is removed, for example by suitable thinning process, to expose the epitaxial layer 220 on the top surface.

A plurality of semiconductor fins FS2 are formed. The semiconductor fins FS1 may extend substantially along a direction X. In various embodiments, each of the fins FS2 includes portions of each of the epitaxial layers 222 and 224 of the epitaxial stack 220. The fins FS2 may be fabricated using suitable processes including photolithography and etch processes. The fabrication process of the fins FS2 may be similar to that of fins FS1, and not repeated herein.

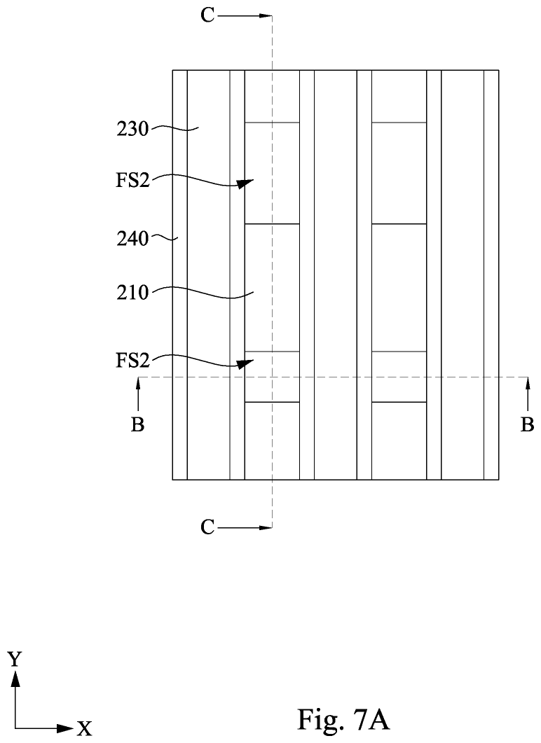

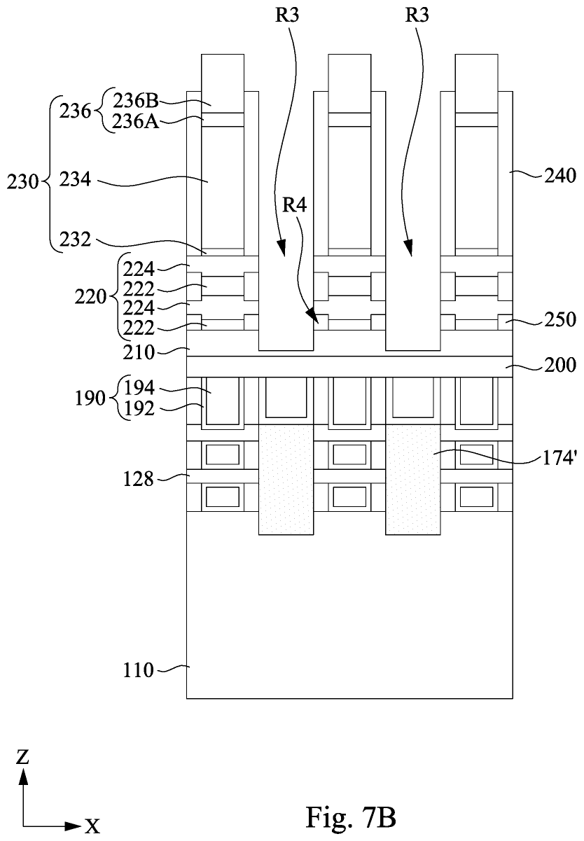

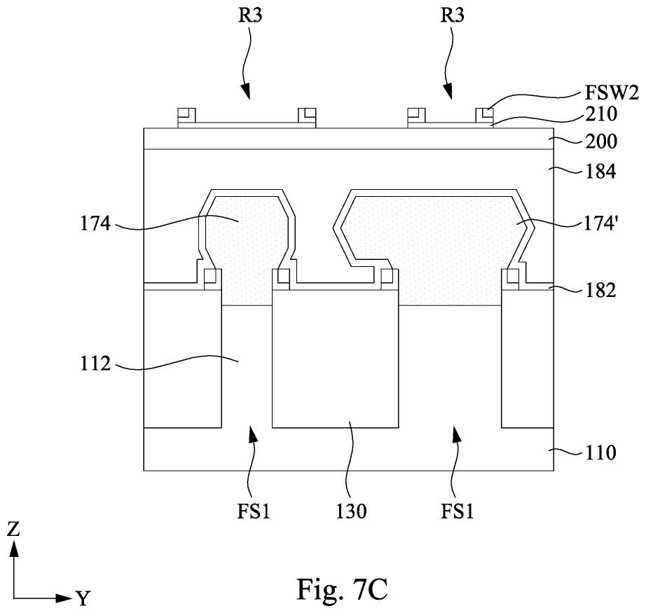

Reference is made to FIGS. 7A-7C. One or more dummy gate structures 230 are formed on the epitaxial stack 220. The dummy gate structure 230 may include a gate dielectric 232, a gate electrode 234, and a hard mask 236. The gate dielectric 232 may include one or more layers of dielectric material, such as silicon oxide, silicon nitride, a high-k dielectric material, and/or other suitable dielectric material. In some embodiments, the gate electrode 234 includes a material different than that of the gate dielectric 232. In some embodiments, the gate dielectric 232 may be deposited by a CVD process, a sub-atmospheric CVD (SACVD) process, a FCVD process, an ALD process, a PVD process, or other suitable process. The gate electrode 144 may include polycrystalline silicon (polysilicon). The hard mask 236 may include a silicon oxide layer 236A and a silicon nitride layer 236B over the silicon oxide layer 236A. In some embodiments, the materials of the dummy gate structures 230 are formed by various processes such as layer deposition, for example, CVD, PVD, ALD, thermal oxidation, or other suitable deposition techniques, or combinations thereof.

The dummy gate structures 230 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS2 are partially exposed on opposite sides of the dummy gate structure 230.

Gate spacers 240 are formed on opposite sidewalls of the dummy gate structures 230. The spacers 240 may be made of a dielectric material such as silicon oxide, silicon nitride, silicon carbide, silicon oxynitride, SiCN, silicon oxycarbide, SiOCN, and/or combinations thereof. In some embodiments, each of the spacers 240 includes a single layer or multiple layers. In some embodiments, fin sidewall spacers FSW2 are formed on opposite sides of the fins FS2. The fin sidewall spacers FSW2 may be made of a dielectric material such as silicon oxide, silicon nitride, silicon carbide, silicon oxynitride, SiCN, silicon oxycarbide, SiOCN, and/or combinations thereof. The gate spacers 240 or/and the fin sidewall spacers FSW2 may be formed by first depositing one or more conformal spacer material layers and subsequently etching back the one or more spacer material layers to form the gate spacers 240 or/and the fin sidewall spacers FSW2. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS2, leaving the gate spacers 240 or/and the fin sidewall spacers FSW2 on the vertical surfaces, such as the sidewalls of the dummy gate structures 230 and sidewalls of the fins FS2.

After formation of the dummy gate structures 230 and the gate spacers 240, exposed portions of the semiconductor fins FS2 that extend laterally beyond the gate spacers 240 (e.g., in source/drain regions of the fins FS2) are etched by using, for example, an anisotropic etching process that uses the dummy gate structures 230 and the gate spacers 240 as an etch mask, resulting in recesses R3 into the semiconductor fins FS2 and between corresponding dummy gate structures 230. After the anisotropic etching, end surfaces of the sacrificial layers 222 and the channel layers 224 are exposed by the recesses R3 and aligned with respective outermost sidewalls of the gate spacers 240, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. Through the etching process(es), top ends of the fin sidewall spacers FSW2 may be lowered to a position below tops of the fins FS2 (referring to FIG. 6C). In some alternatively embodiments, the fin sidewall spacers FSW2 are entirely removed by etching the recesses R3.

The sacrificial layers 222 are laterally or horizontally recessed by using suitable selective etching process, resulting in lateral/sidewall recesses R4 vertically between corresponding channel layers 224, and vertically between the channel layer 224 and the second dielectric layer 210. For example, end surfaces of the sacrificial layers 222 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The channel layers 224 may have a higher etch resistance to the selective etching process than that of the sacrificial layers 222. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 224 may not be not significantly etched by the process of laterally recessing the sacrificial layers 222. As a result, the channel layers 224 laterally extend past opposite end surfaces of the sacrificial layers 222.

Inner spacers 250 are formed in the recesses R4. Stated differently, the inner spacers 250 may be formed on opposite end surfaces of the laterally recessed sacrificial layers 222. The inner spacers 250 may include a low-k dielectric material, such as SiOₓ, SiON, SiOC, SiN, SiCN, or SiOCN. Formation of the inner spacers 250 may include depositing an inner spacer material layer, followed by an anisotropic etching process to trim the deposited inner spacer material layer. Through the anisotropic etching process, only portions of the deposited inner spacer material layer that fill the lateral/sidewall recesses R4 are left. The inner spacers 250 may include a single layer or multiple layers. The inner spacers 250 may serve to isolate metal gates from source/drain regions formed in subsequent processing. In the example of FIG. 7B, sidewalls of the inner spacers 250 are aligned with sidewalls of the channel layers 224.

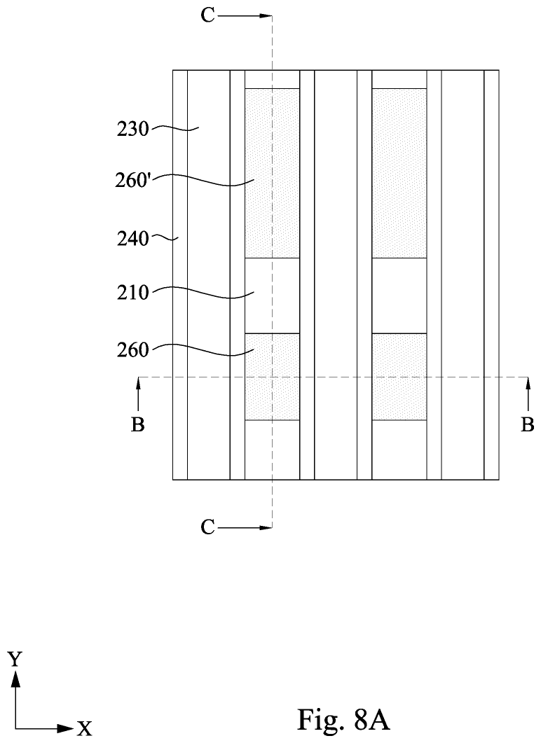

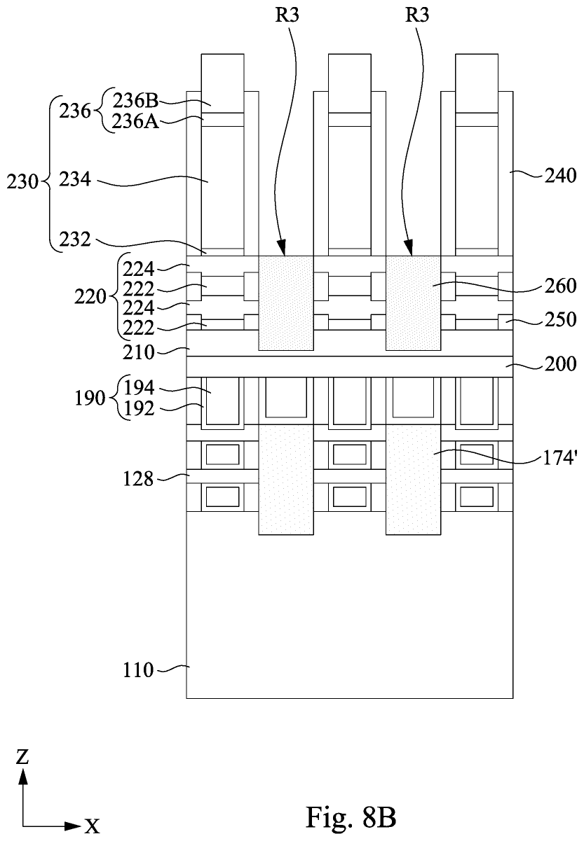

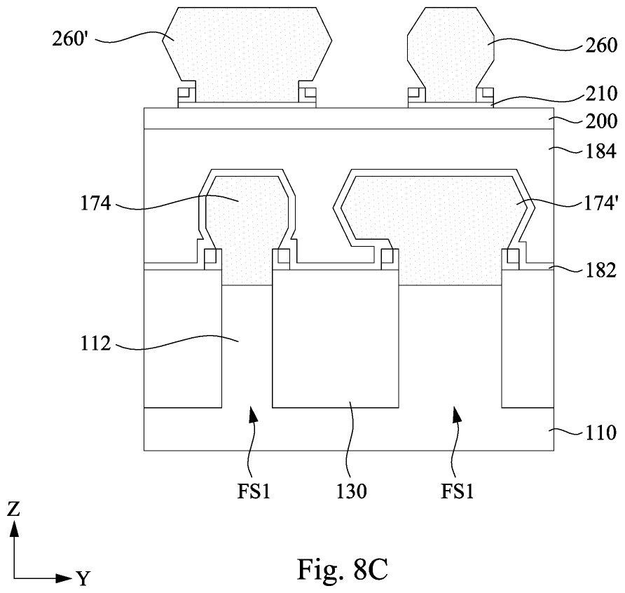

Reference is made to FIGS. 8A-8C. The source/drain epitaxial structures 260 or/and 260′ are formed in the recess R3 and in contact with opposite sides of the channel layers 224. In some embodiments, the source/drain epitaxial structures 260 and 260′ may include Ge, Si, GaAs, AlGaAs, SiGe, GaAsP, SiP, or other suitable material. The source/drain epitaxial structures 260 or/and 260′ may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 260 and 260′ are not in-situ doped, an implantation process (i.e., a junction implant process) is performed to dope the source/drain epitaxial structures 260 and 260′. The source/drain epitaxial structures 260 and 260′ may be formed by performing an epitaxial growth process that provides an epitaxial material on the exposed surfaces of the channel layers 224. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 224.

In some embodiments of the present disclosure, the source/drain epitaxial structures 260 and 260′ are formed with different sizes/widths. For example, a width of the source/drain epitaxial structures 260′ are greater than a width of the source/drain epitaxial structures 260. The sizes/widths of the source/drain epitaxial structures 260 and 260′ can be tuned by deposition parameters in the epitaxial growth process.

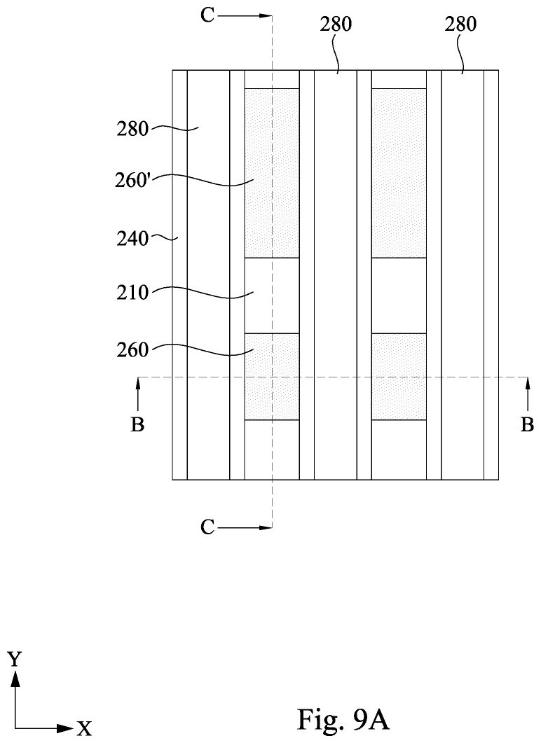

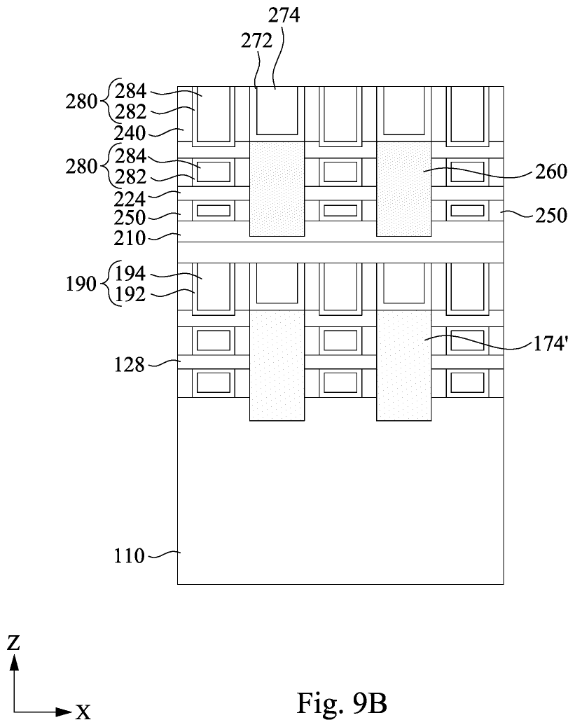

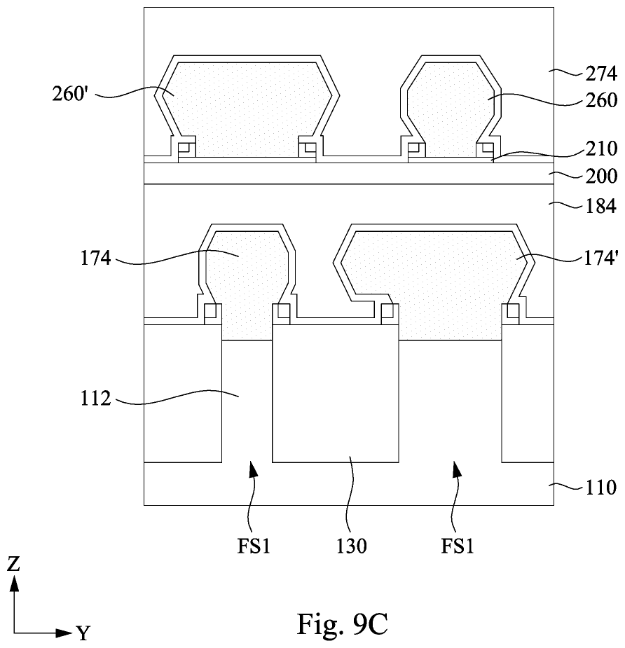

Reference is made to FIGS. 9A-9C. After the formation of the source/drain epitaxial structures 260 and 260′, an etch stop layer (ESL) 272 and an interlayer dielectric (ILD) layer 274 are formed. In some examples, the ESL layer 272 includes a silicon nitride layer, silicon oxide layer, a silicon oxynitride layer, and/or other suitable materials. The ESL layer 272 may be formed by plasma-enhanced chemical vapor deposition (PECVD) process and/or other suitable deposition or oxidation processes. In some embodiments, the ILD layer 274 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 272. The ILD layer 274 may be deposited by a CVD process or other suitable deposition technique.

The dummy gate structure 230 and the sacrificial layer 222 (referring to FIGS. 8A and 8B) are replaced with a high-k/metal gate structure 280. The dummy gate structures 230 (referring to FIGS. 8A and 8B) are removed, followed by removing the sacrificial layers 222 (referring to FIG. 8B). For example, the dummy gate structures 230 (referring to FIGS. 8A and 8B) are removed by using a selective etching process (e.g., selective dry etching, selective wet etching, or a combination thereof) that etches the materials in dummy gate structures 230 (referring to FIGS. 8A and 8B) at a faster etch rate than it etches other materials (e.g., the gate spacers 240, the ESL layer 272, and/or the ILD layer 274), thus resulting in gate trenches between corresponding gate spacers 240, with the sacrificial layers 222 (referring to FIG. 8B) exposed in the gate trenches. Subsequently, the sacrificial layers 222 (referring to FIG. 8B) in the gate trenches are etched by using another selective etching process that etches the sacrificial layers 222 at a faster etch rate than it etches the layers 224, thus forming openings/spaces between neighboring layers 224. The openings/spaces may expose the sidewalls of the inner spacers 250. In this way, the channel layers 224 become nanosheets suspended over the substrate 110 and between the source/drain epitaxial structures 260/260′. This step is also called a channel release process. At this interim processing step, the openings/spaces surrounding the nanosheets 224 may be filled with ambient environment conditions (e.g., air, nitrogen, etc). In some embodiments, the nanosheets 224 can be interchangeably referred to as nanowires, nanoslabs and nanorings, depending on their geometry. For example, in some other embodiments, the channel layers 224 may be trimmed to have a substantial rounded shape (i.e., cylindrical) due to the selective etching process for completely removing the sacrificial layers 222 (referring to FIG. 8B). In that case, the resultant channel layers 224 can be called nanowires.

In some embodiments, the sacrificial layers 222 (referring to FIG. 8B) are removed by using a selective dry etching process. In some embodiments, the sacrificial layers 222 (referring to FIG. 8B) are SiGe and the channel layers 224 are silicon allowing for the selective removal of the sacrificial layers 222 (referring to FIG. 8B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 222 (referring to FIG. 8B) are removed. Moreover, because oxidation rate of Si is much lower (sometimes 30 times lower) than oxidation rate of SiGe, the channel layers 224 may remain substantially intact during the channel release process.

Replacement gate structures 280 are then respectively formed in the gate trenches to surround each of the nanosheets 224 suspended in the gate trenches. The gate structures 280 may be final gates of GAA FETs. The final gate structure may be a high-k/metal gate stack, however other compositions are possible. In some embodiments, each of the gate structures 280 forms the gate associated with the multi-channels provided by the plurality of nanosheets 224. For example, the high-k/metal gate structures 280 are formed within the openings/spaces provided by the release of nanosheets 224. The high-k/metal gate structures 280 may be between the layers 224 and surrounded by the inner spacers 250.

In various embodiments, the high-k/metal gate structure 280 includes a gate dielectric layer 282 formed around the nanosheets 224 and a gate metal layer 284 formed around the gate dielectric layer 282 and filling a remainder of the gate trenches. Formation of the high-k/metal gate structures 280 may include one or more deposition processes to form various gate materials, followed by a CMP processes to remove excessive gate materials, resulting in the high-k/metal gate structures 280 having top surfaces level with a top surface of the ILD layer 274. Thus, transistors (e.g., GAA FET) are formed, and the high-k/metal gate structure 280 surrounds each of the nanosheets 224, and thus is referred to as a gate of the transistors (e.g., GAA FET).

The gate dielectric layer 282 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the layers 224 exposed in the gate trenches are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 284 includes one or more metal layers. For example, the gate metal layer 284 may include one or more work function metal layers stacked one over another and a fill metal filling up a remainder of gate trenches. The one or more work function metal layers in the gate metal layer 284 provide a suitable work function for the high-k/metal gate structures 280. For an n-type GAA FET, the gate metal layer 284 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 284 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 284 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In a CFET architecture, nMOS and pMOS devices are stacked on top of each other. Stacking removes the n-p spacing from cell height considerations. This allows further maximization of the effective channel width, and, hence, the drive current. For example, the high-k/metal gate structures 280 are respectively stacked on top of the high-k/metal gate structures 190, and the source/drain epitaxial structures 260 and 260′ are respectively stacked on top of the source/drain epitaxial structures 174′ and 174. In some embodiments where the n-type GAA FET is stacked over the p-type GAA FET, the gate metal layer 284 includes one or more n-type work function metal (N-metal) layers, the source/drain epitaxial structures 260 and 260′ are doped with n-type dopants, the gate metal layer 194 includes one or more p-type work function metal (P-metal) layers, and the source/drain epitaxial structures 174 and 174′ are doped with p-type dopants. In some alternative embodiments where the p-type GAA FET is stacked over the n-type GAA FET, the gate metal layer 284 includes one or more p-type work function metal (P-metal) layers, the source/drain epitaxial structures 260 and 260′ are doped with p-type dopants, the gate metal layer 194 includes one or more n-type work function metal (N-metal) layers, and the source/drain epitaxial structures 174 and 174′ are doped with n-type dopants.

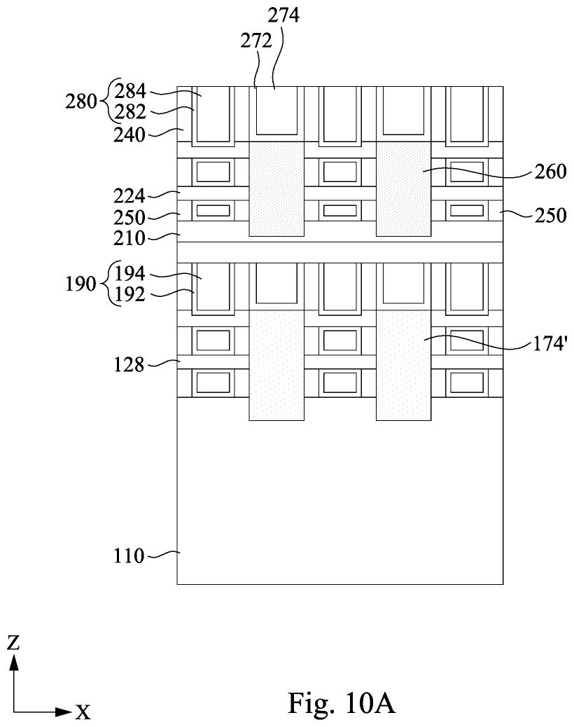

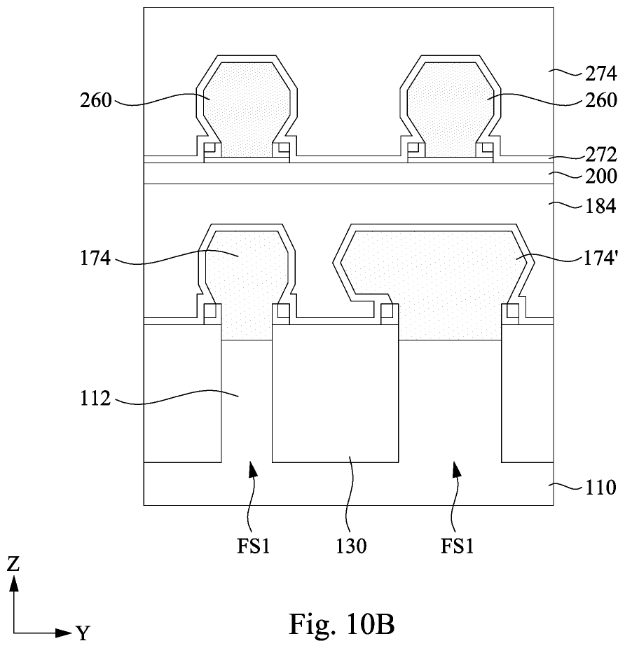

FIGS. 10-13B illustrate schematic views of intermediate stages in the manufacture of an integrated circuit device in accordance with some embodiments of the present disclosure. FIGS. 10A, 11A, 12A, and 12A are cross-sectional views of the integrated circuit device (e.g., taken along line B-B in FIGS. 2A, 3A, 4A, 5A, 6A, 7A, 8A, and 9A) at various manufacturing stages in accordance with some embodiments. FIGS. 10B, 111B, 12B, and 13B are cross-sectional views of the integrated circuit device (e.g., taken along line C-C in FIGS. 2A, 3A, 4A, 5A, 6A, 7A, 8A, and 9A) at various manufacturing stages in accordance with some embodiments. It is understood that additional steps may be provided before, during, and after the steps shown in FIGS. 10A-13B, and some of the steps described below can be replaced or eliminated for additional embodiments of the method. The order of the operations/processes may be interchangeable.

FIGS. 10A and 10B are cross-sectional views of an integrated circuit device obtained through the manufacture process in FIGS. 2A-9C. Details of the integrated circuit device in FIGS. 10A and 10B are similar to that of FIGS. 9A-9C, except that the integrated circuit device in FIGS. 10A and 10B includes source/drain epitaxial structures 260 respectively stacked on top of the source/drain epitaxial structures 174′ and 174. As aforementioned, the sizes/widths of the source/drain epitaxial structures can be tuned by deposition parameters in the epitaxial growth process. Other details regarding the integrated circuit device in FIGS. 10A and 10B are similar those aforementioned, and thereto not repeated herein.

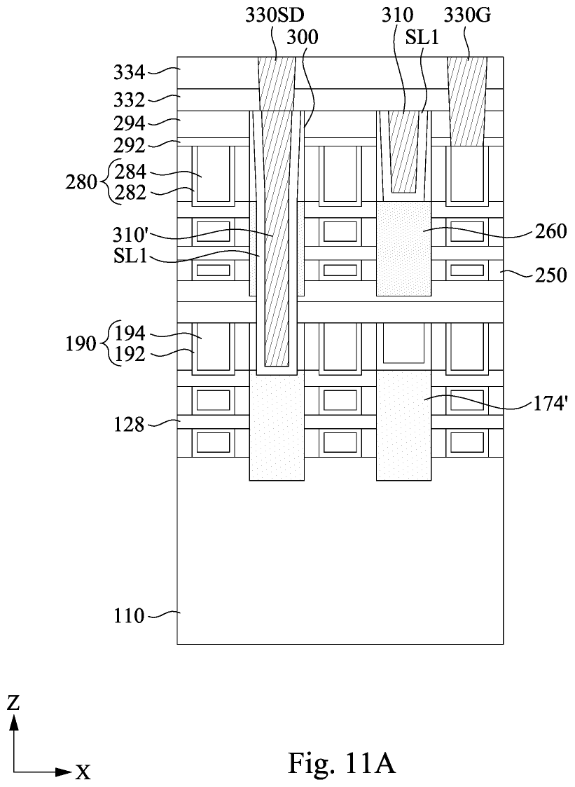

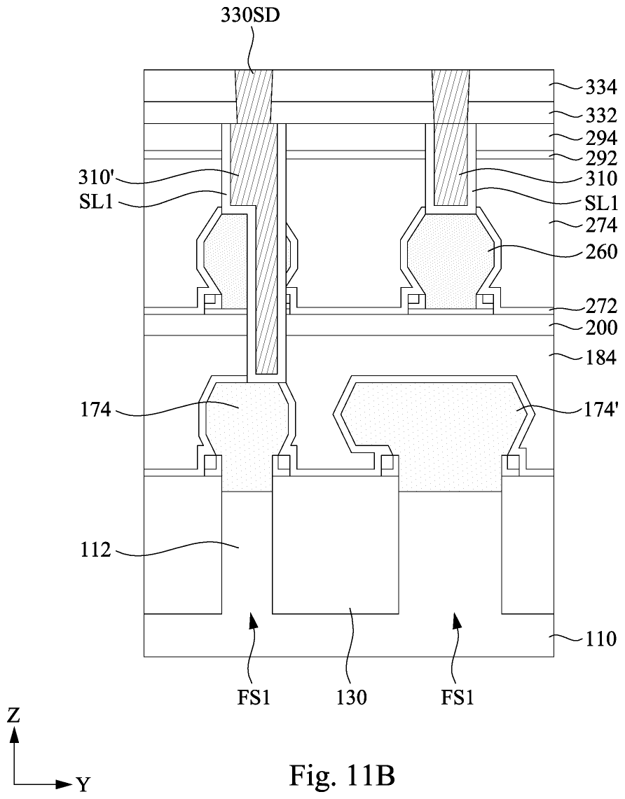

Reference is made to FIGS. 11A and 11B. An etch stop layer (ESL) 292 and an interlayer dielectric (ILD) layer 294 are formed. In some examples, the ESL layer 292 includes a silicon nitride layer, silicon oxide layer, a silicon oxynitride layer, and/or other suitable materials. The ESL layer 292 may be formed by plasma-enhanced chemical vapor deposition (PECVD) process and/or other suitable deposition or oxidation processes. In some embodiments, the ILD layer 294 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 292. The ILD layer 294 may be deposited by a CVD process or other suitable deposition technique.

Frontside contact plugs 310 and 310′ are formed for providing electrical connection to the source/drain epitaxial structures 260. For example, one or more first etching processes are performed to first form contact openings by removing portions of the ILD layer 294, the ESL layer 292, the ILD layer 274, and the ESL layer 272. The contact openings may extend through the ILD layer 294, the ESL layer 292, the ILD layer 274, and the ESL layer 272, and expose top surfaces of the source/drain epitaxial structures 260. Prior to the first etching processes, a lithography process may be performed to form a photoresist, which may then serve as an etch mask during the first etching processes. In some embodiments, dielectric liners 300 are formed in the contact opening, and the dielectric liners 300 may include a silicon nitride layer, a silicon oxynitride layer, and/or other suitable materials having a different etch selectivity than the ILD layer 294. Subsequently, one or more second etching processes are performed to deepen some of the contact openings by removing the source/drain epitaxial structure 260 and the underlying dielectric materials. Prior to the second etching processes, a lithography process may be performed to form a photoresist, which may then serve as an etch mask during the second etching processes. The deepened contact opening may extend through the ILD layer 294, the ESL layer 292, the ILD layer 274, and the ESL layer 272, the source/drain epitaxial structure 260, the second dielectric layer 210, the first dielectric layer 200, the ILD layer 184, and the ESL layer 182, and exposes a top surface of the source/drain epitaxial structure 174.

Frontside contact plugs 310 and 310′ are then formed. The contact plug 310 is formed in the contact opening and in contact with the source/drain epitaxial structures 260. The contact plug 310′ is formed in the deepened contact opening and in contact with the source/drain epitaxial structures 260 and 174. Each of the contact plugs 310 and 310′ may include a barrier layer and a fill metal. The barrier layer may be made of TiN, TaN, or combinations thereof. In some embodiments, the fill metal may be made of metal, such as W, Co, Ru, Al, Cu, or other suitable materials. These materials are deposited into the contact opening by suitable deposition processes. After the deposition of the contact materials, a planarization process, such as a chemical mechanical polish (CMP) process, may be then performed.

In some embodiments, prior to the formation of the contact plugs 310 and 310′, metal silicide layers SL1 are respectively formed in the contact openings and over the exposed frontside of the source/drain epitaxial structures 260 and 174. The metal silicide layers SL1 may be formed by suitable deposition process and silicidation process. The metal silicide layers SL1 may include silicides of nickel, cobalt, titanium, tantalum, platinum, tungsten, other noble metals, other refractory metals, rare earth metals or their alloys.

An ESL layer 332 and an ILD layer 334 are formed over the contact plugs 310 and 310′. In some examples, the ESL layer 332 includes a silicon nitride layer, silicon oxide layer, a silicon oxynitride layer, and/or other suitable materials having a different etch selectivity than the ILD layer 334. The ESL layer 332 may be formed by plasma-enhanced chemical vapor deposition (PECVD) process and/or other suitable deposition or oxidation processes. In some embodiments, the ILD layer 334 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 332. The ILD layer 334 may be deposited by a CVD process or other suitable deposition technique.

Front-side conductive vias 330SD are formed through the ILD layer 334 and the ESL layer 332, for providing electrical connection to the contact plugs 310 and 310′. Conductive vias 330G are formed through the ILD layer 334, the ESL layer 332, the ILD layer 294, and the ESL layer 292, for providing electrical connection to the high-k/metal gate structure 280. Formation of the conductive vias 330SD and 330G includes etching openings in the ILD layer 334 and the ESL layer 332 and etching an opening in the ILD layer 334, the ESL layer 332, the ILD layer 294, and the ESL layer 292, depositing conductive materials into the openings, followed by a CMP process.

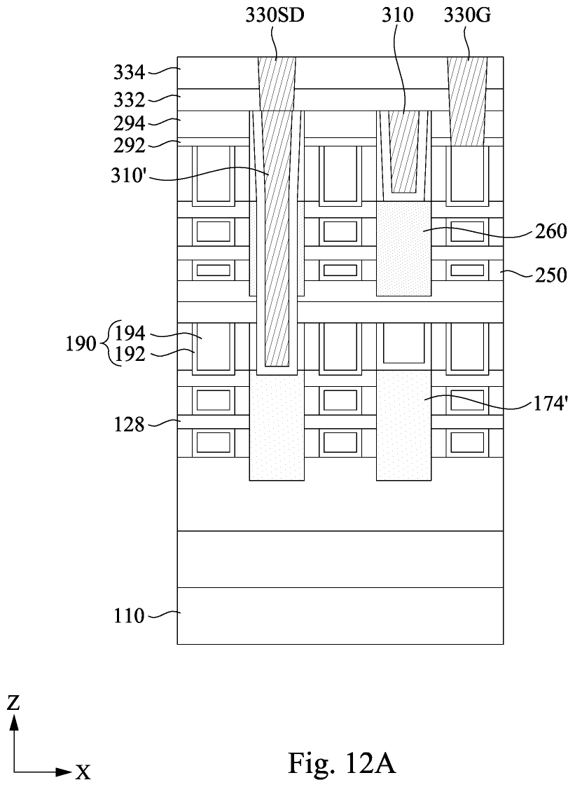

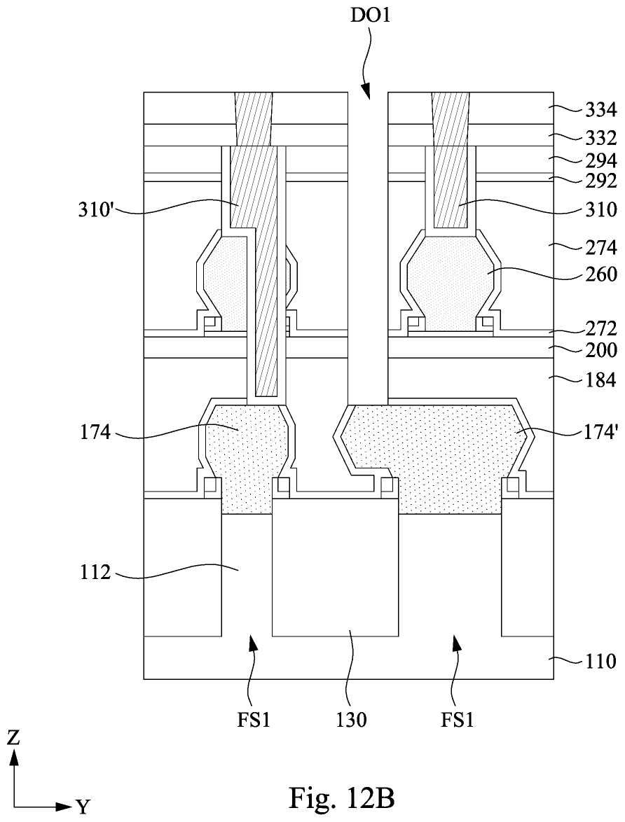

Reference is made to FIGS. 12A and 12B. A deep contact opening DO1 is formed through the ILD layer 334, the ESL layer 332, the ILD layer 294, the ESL layer 292, the ILD layer 274, the ESL layer 272, the first dielectric layer 200, the ILD layer 184, the ESL layer 182, and exposes a top surface of the source/drain epitaxial structure 174′. The deep contact opening DO1 does not expose the source/drain epitaxial structure 260 stacked over the source/drain epitaxial structure 174′. Formation of the deep contact opening DO1 may include a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. The etch process may removes portions of the ILD layer 334, the ESL layer 332, the ILD layer 294, the ESL layer 292, the ILD layer 274, the ESL layer 272, the first dielectric layer 200, the ILD layer 184, the ESL layer 182 using the photoresist as etch mask, thereby forming the deep opening DO1. After the etch process, the photoresist is removed by suitable removal process.

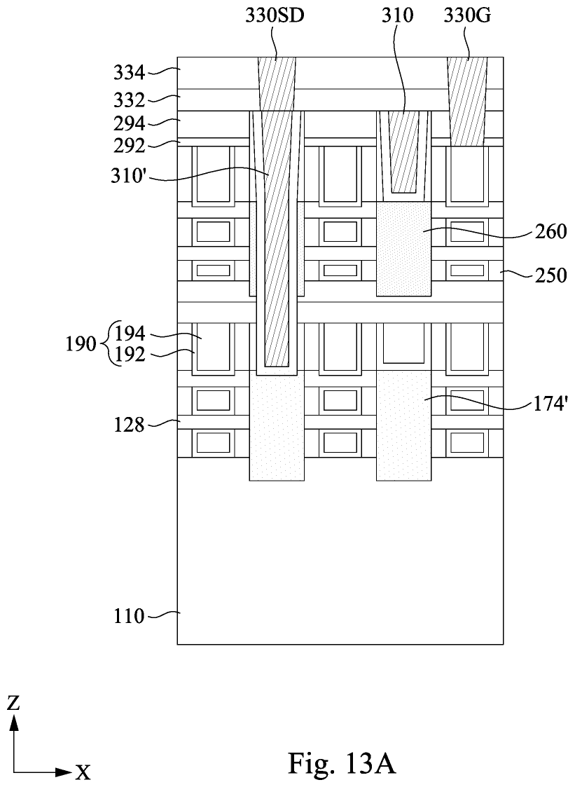

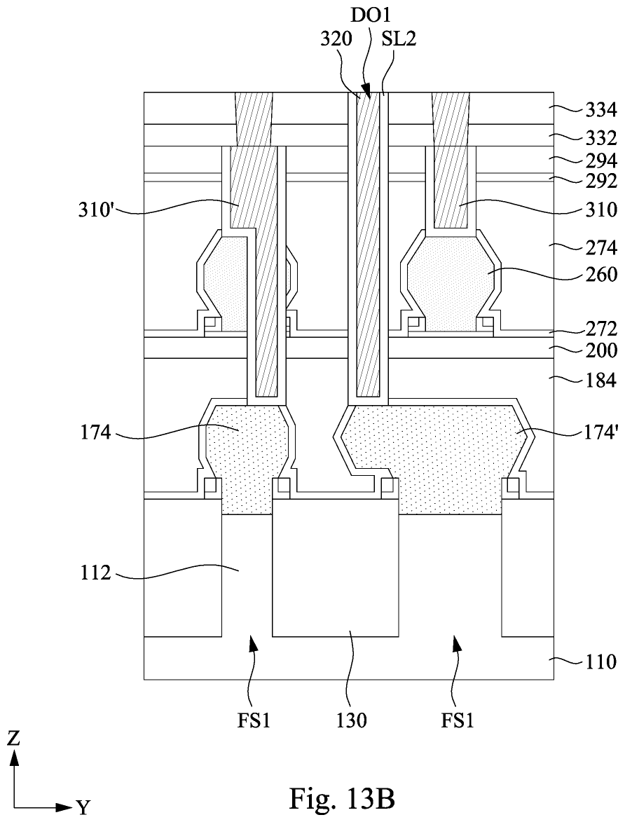

Reference is made to FIGS. 13A and 13B. A deep contact plug 320 is then formed. The deep contact plug 320 is formed in the deep contact opening DO1 and in contact with the source/drain epitaxial structures 174′. The deep contact plug 320 is not in contact with the source/drain epitaxial structure 260 stacked over the source/drain epitaxial structures 174′. The deep contact plug 320 may include a barrier layer and a fill metal. The barrier layer may be made of TiN, TaN, or combinations thereof. In some embodiments, the fill metal may be made of metal, such as W, Co, Ru, Al, Cu, or other suitable materials. These materials are deposited into the deep contact opening DO1 by suitable deposition processes. After the deposition of the contact materials, a planarization process, such as a CMP process, may be then performed. In some embodiments, prior to the formation of the deep contact plugs 320, metal silicide layers SL2 are respectively formed in the contact openings and over the exposed frontside of the source/drain epitaxial structures 174′. The metal silicide layers SL2 may be formed by suitable deposition process and silicidation process. The metal silicide layers SL2 may include silicides of nickel, cobalt, titanium, tantalum, platinum, tungsten, other noble metals, other refractory metals, rare earth metals or their alloys. Other details of the present embodiments are similar to those mentioned above, and therefore not repeated herein.

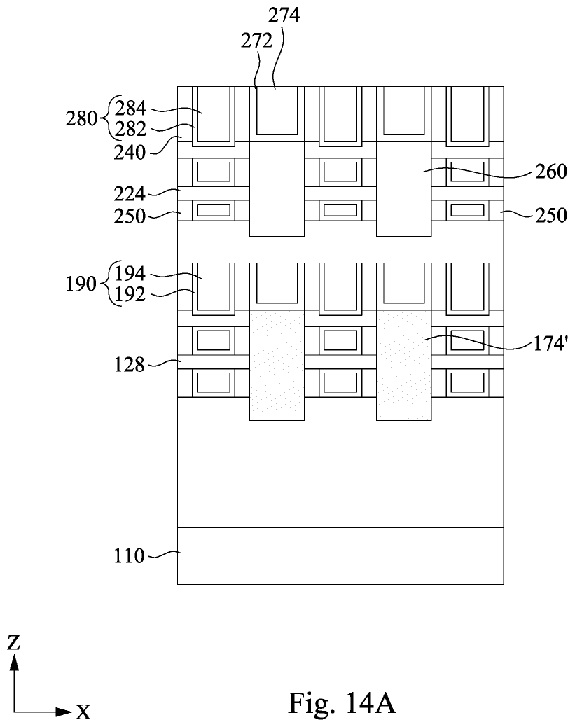

FIGS. 14A-18B illustrate schematic views of intermediate stages in the manufacture of an integrated circuit device in accordance with some embodiments of the present disclosure. FIGS. 14A, 15A, 16A, and 17A are cross-sectional views of the integrated circuit device (e.g., taken along line B-B in FIGS. 2A, 3A, 4A, 5A, 6A, 7A, 8A, and 9A) at various manufacturing stages in accordance with some embodiments. FIGS. 14B, 15B, 16B, and 17B are cross-sectional views of the integrated circuit device (e.g., taken along line C-C in FIGS. 2A, 3A, 4A, 5A, 6A, 7A, 8A, and 9A) at various manufacturing stages in accordance with some embodiments. It is understood that additional steps may be provided before, during, and after the steps shown in FIGS. 14A-18B, and some of the steps described below can be replaced or eliminated for additional embodiments of the method. The order of the operations/processes may be interchangeable.

FIGS. 14A and 14B are cross-sectional views of an integrated circuit device obtained through the manufacture process in FIGS. 2A-9C. Details of the integrated circuit device in FIGS. 14A and 14B are similar to that of FIGS. 9A-9C, except that the integrated circuit device in FIGS. 14A and 14B includes source/drain epitaxial structures 260 and 260′ respectively stacked on top of the source/drain epitaxial structures 174. As aforementioned, the sizes/widths of the source/drain epitaxial structures can be tuned by deposition parameters in the epitaxial growth process. Other details regarding the integrated circuit device in FIGS. 14A and 14B are similar those aforementioned, and thereto not repeated herein.

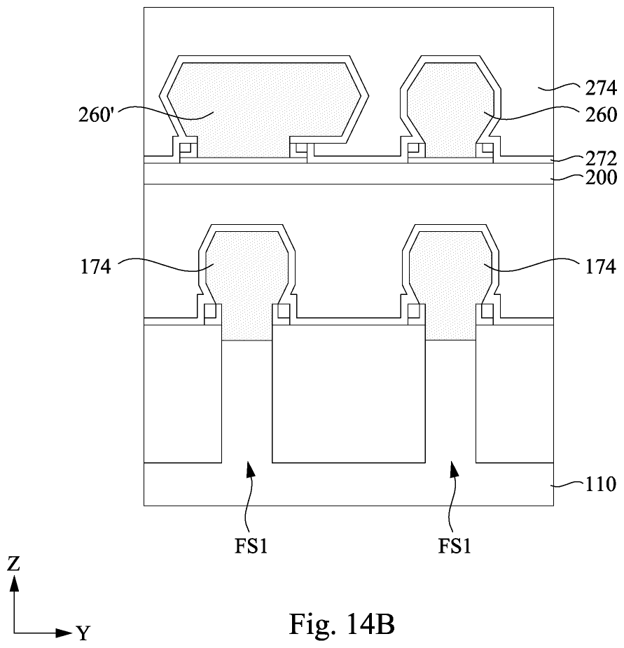

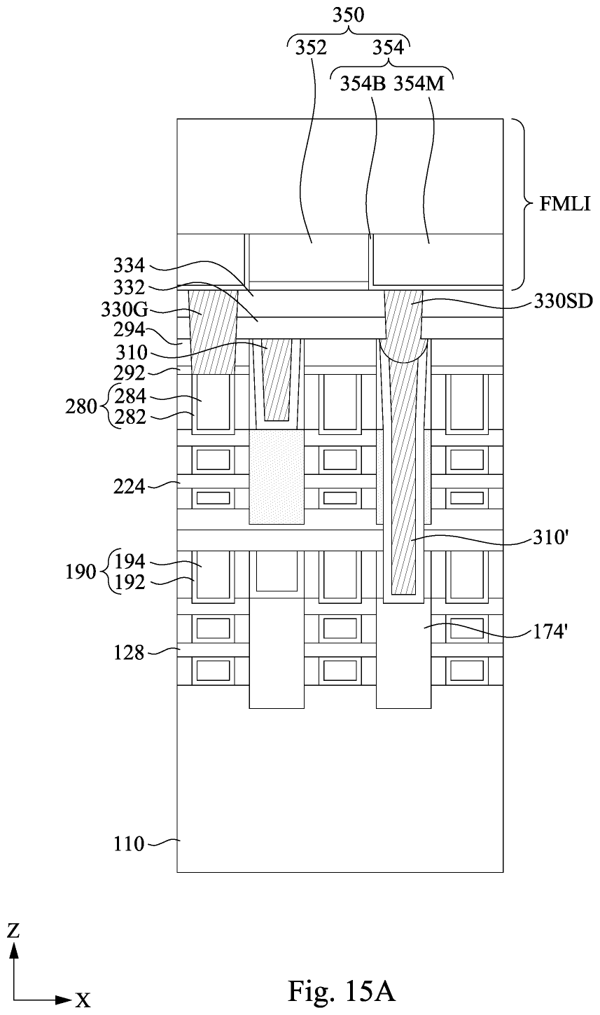

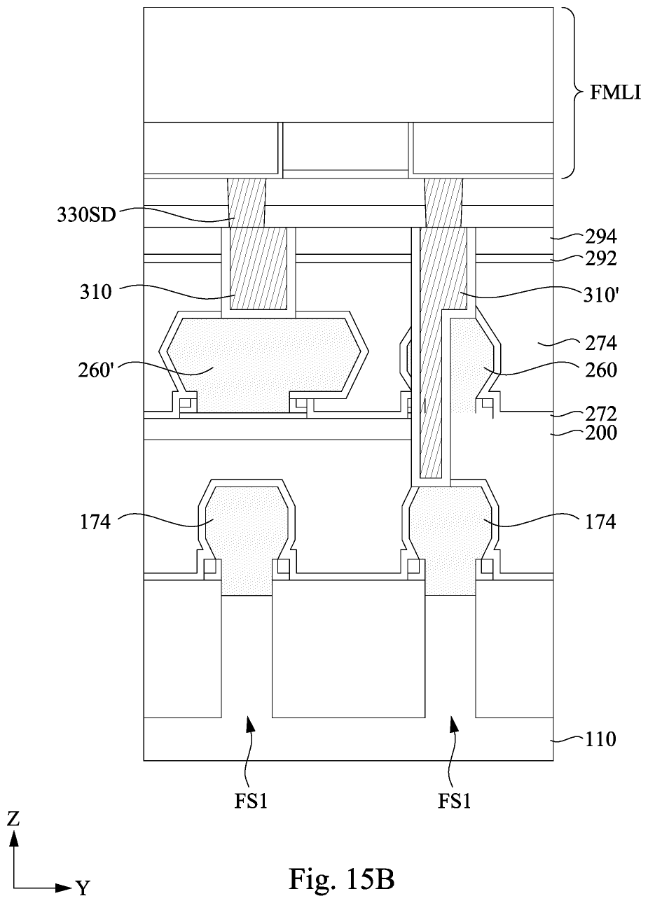

Reference is made to FIGS. 15A and 15B. An ESL 292 and an ILD layer 294 are formed. Frontside contact plugs 310 and 310′ are formed for providing electrical connection to the source/drain epitaxial structures 260 and 260′. An ESL layer 332 and an ILD layer 334 are formed over the contact plugs 310 and 310′. Conductive vias 330SD are formed through the ILD layer 334 and the ESL layer 332, for providing electrical connection to the contact plugs 310 and 310′. Conductive vias 330G are formed through the ILD layer 334, the ESL layer 332, the ILD layer 294, and the ESL layer 292, for providing electrical connection to the high-k/metal gate structure 280. Formation of the conductive vias 330SD and 330G includes etching openings in the ILD layer 334 and the ESL layer 332 and etching an opening in the ILD layer 334, the ESL layer 332, the ILD layer 294, and the ESL layer 292, depositing conductive materials into the openings, followed by a CMP process.

A front-side multilayer interconnection (MLI) structure FMLI may be formed over the substrate 110. The front-side MLI structure FMLI may include a plurality of front-side metallization layers. The number of front-side metallization layers may vary according to design specifications of the integrated circuit. The front-side metallization layers each comprise a front-side inter-metal dielectric (IMD) layer, one or more horizontal interconnects, such as front-side metal lines, respectively extending horizontally or laterally in the front-side IMD layer, and vertical interconnects, such as front-side conductive vias, respectively extending vertically in the front-side IMD layer. For example, a bottommost metallization layer 350 is contained in the front-side MLI structure FMLI. The bottommost metallization layer 350 may include IMD layer 352 and front-side metal lines 354. The front-side metal lines 354 may include a metal barrier layer 354B and a metal material 354M surrounded by the metal barrier layer 354B.

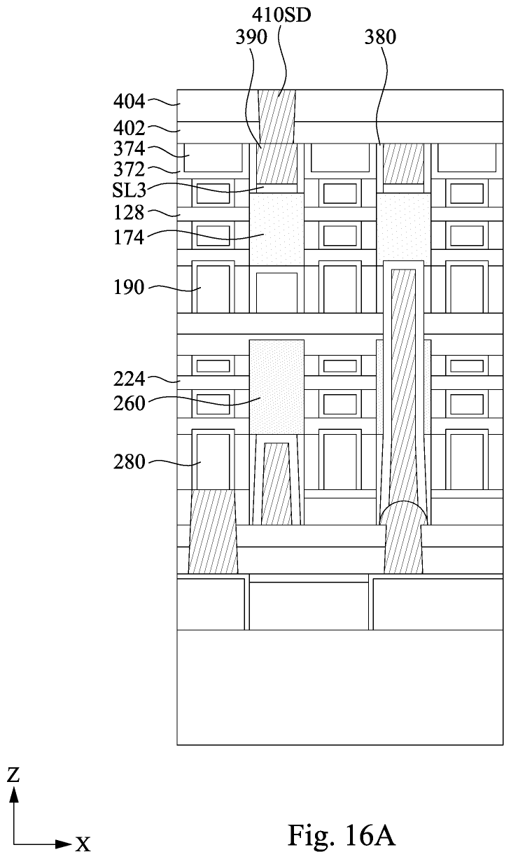

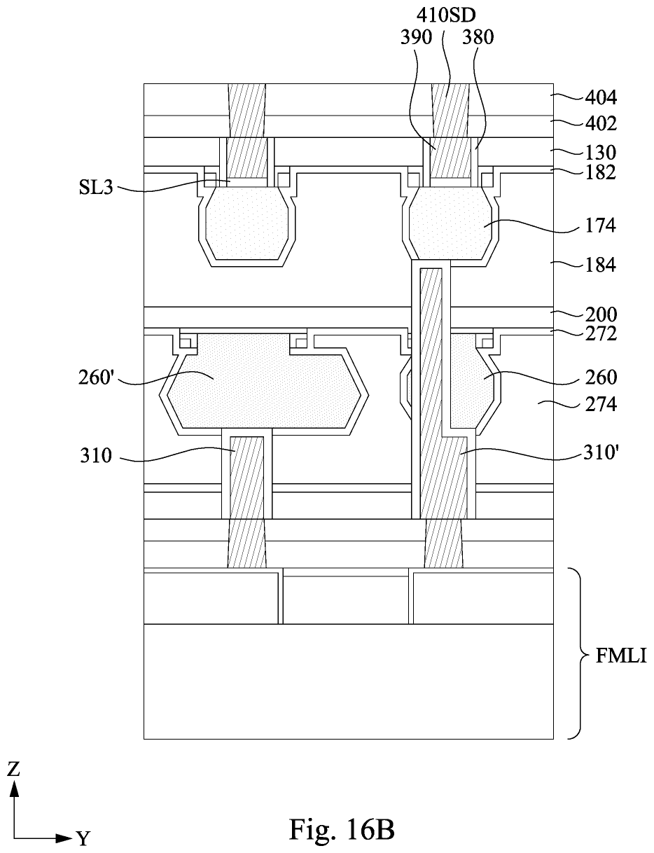

Reference is made to FIGS. 16A and 16B. The wafer may be flipped upside-down, backside contact plugs 390 are formed for providing electrical connection to the source/drain epitaxial structures 174. Prior to the formation of the backside contact plugs 390, the semiconductor substrate 110 (referring to FIGS. 15A and 15B) is removed by suitable etching and/or planarization process, thereby exposing the source/drain epitaxial structures 174 (referring to FIGS. 15A and 15B). An ESL layer 372 and an ILD layer 374 are formed around the source/drain epitaxial structures 174 (referring to FIGS. 14A and 14B). In some examples, the ESL layer 372 includes a silicon nitride layer, silicon oxide layer, a silicon oxynitride layer, and/or other suitable materials. The ESL layer 372 may be formed by plasma-enhanced chemical vapor deposition (PECVD) process and/or other suitable deposition or oxidation processes. In some embodiments, the ILD layer 374 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 372. The ILD layer 374 may be deposited by a CVD process or other suitable deposition technique.

The source/drain epitaxial structures 174 are subsequently removed to leave contact openings between the ILD layers 374. In some embodiments, dielectric liners 380 are formed in the contact opening, and the dielectric liners 380 may include a silicon nitride layer, a silicon oxynitride layer, and/or other suitable materials having a different etch selectivity than the ILD layer 184.

Backside contact plugs 390 are then formed. The contact plug 390 is formed in the contact opening and in contact with the source/drain epitaxial structures 174. Each of the contact plugs 390 may include a barrier layer and a fill metal. The barrier layer may be made of TiN, TaN, or combinations thereof. In some embodiments, the fill metal may be made of metal, such as W, Co, Ru, Al, Cu, or other suitable materials. These materials are deposited into the contact opening by suitable deposition processes. After the deposition of the contact materials, a planarization process, such as a chemical mechanical polish (CMP) process, may be then performed. In some embodiments, prior to the formation of the contact plugs 390, metal silicide layers SL3 are respectively formed in the contact openings and over the exposed backside of the source/drain epitaxial structures 174. The metal silicide layers SL3 may be formed by suitable deposition process and silicidation process. The metal silicide layers SL3 may include silicides of nickel, cobalt, titanium, tantalum, platinum, tungsten, other noble metals, other refractory metals, rare earth metals or their alloys.

An ESL layer 402 and an ILD layer 404 are formed over the contact plugs 390. In some examples, the ESL layer 402 includes a silicon nitride layer, silicon oxide layer, a silicon oxynitride layer, and/or other suitable materials having a different etch selectivity than the ILD layer 404. The ESL layer 402 may be formed by plasma-enhanced chemical vapor deposition (PECVD) process and/or other suitable deposition or oxidation processes. In some embodiments, the ILD layer 404 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 402. The ILD layer 404 may be deposited by a CVD process or other suitable deposition technique.

Back-side conductive vias 410SD are formed through the ILD layer 404 and the ESL layer 402, for providing electrical connection to the contact plugs 390. Conductive vias 410G are formed through the ILD layer 404, the ESL layer 402, the ILD layer 374, and the ESL layer 372, for providing electrical connection to the high-k/metal gate structure 190. Formation of the conductive vias 410SD and 410G includes etching openings in the ILD layer 404 and the ESL layer 402 and etching an opening in the ILD layer 404, the ESL layer 402, the ILD layer 374, and the ESL layer 372, depositing conductive materials into the openings, followed by a CMP process.

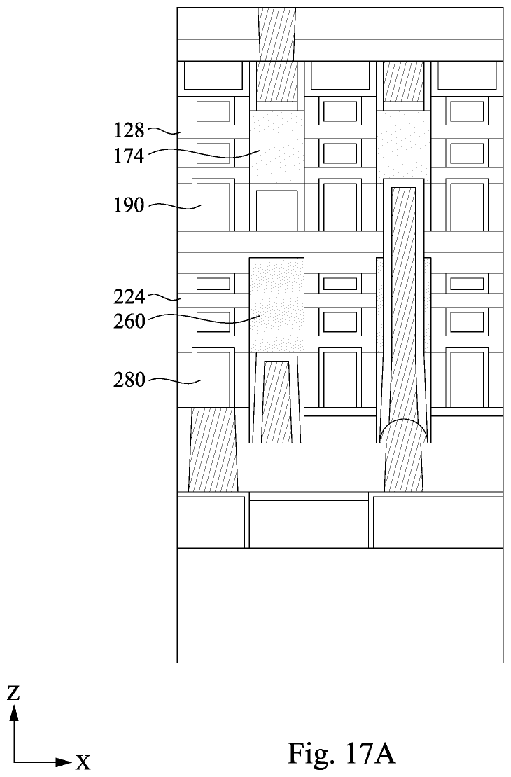

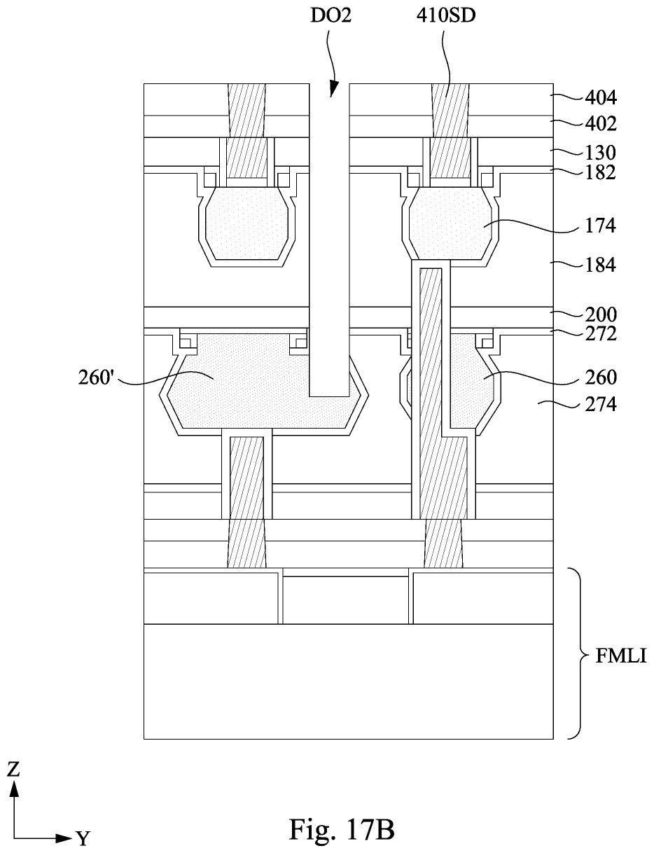

Reference is made to FIGS. 17A and 17B. A deep contact opening DO2 is formed through the ILD layer 404, the ESL layer 402, the isolation structure 130, the ESL layer 182, the ILD layer 184, the first dielectric layer 200, the ESL layer 272, and the ILD layer 274, and exposes a back surface of the source/drain epitaxial structure 260′. The deep contact opening DO2 does not expose the source/drain epitaxial structure 170 vertically stacked with the source/drain epitaxial structure 260′. Formation of the deep contact opening DO2 may include a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. The etch process may removes portions of the ILD layer 404, the ESL layer 402, the isolation structure 130, the ESL layer 182, the ILD layer 184, the first dielectric layer 200, the ESL layer 272, and the ILD layer 274, using the photoresist as etch mask, thereby forming the deep opening DO2. After the etch process, the photoresist is removed by suitable removal process.

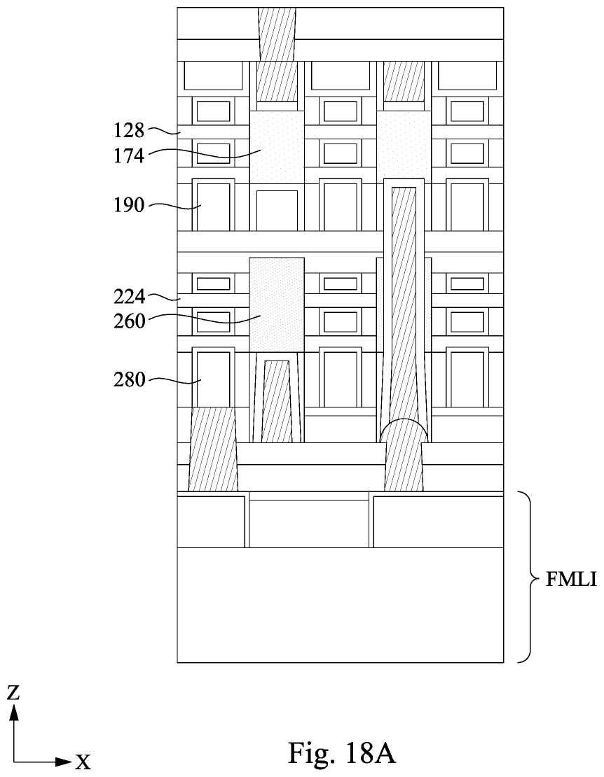

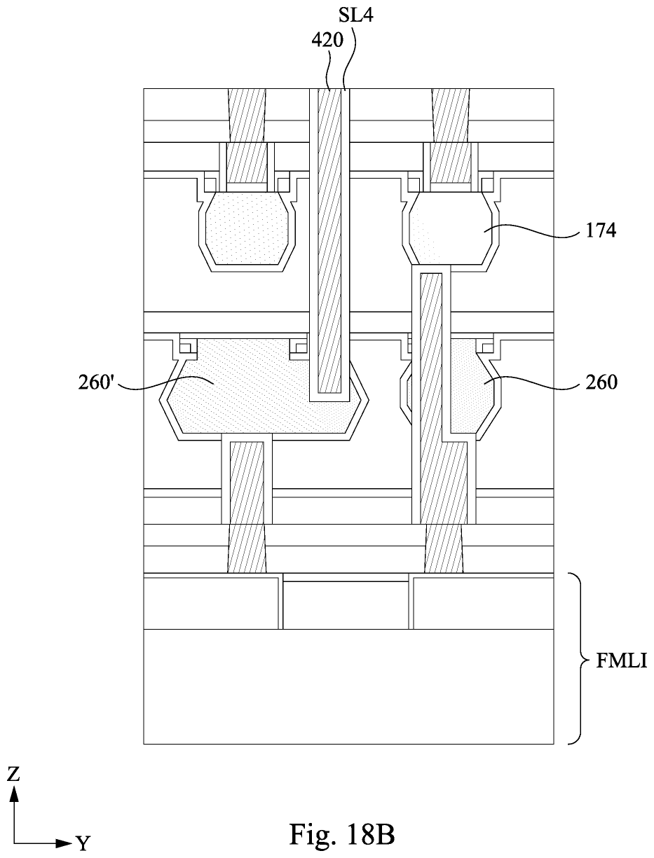

Reference is made to FIGS. 18A and 18B. A deep contact plug 420 is then formed. The deep contact plug 420 is formed in the deep contact opening DO2 and in contact with the source/drain epitaxial structures 260. The deep contact plug 420 is not in contact with the source/drain epitaxial structure 170 vertically stacked with the source/drain epitaxial structure 260′. The deep contact plug 420 may include a barrier layer 422 and a fill metal 424. The barrier layer 422 may be made of TiN, TaN, or combinations thereof. In some embodiments, the fill metal 424 may be made of metal, such as W, Co, Ru, Al, Cu, or other suitable materials. These materials are deposited into the deep contact opening DO1 by suitable deposition processes. After the deposition of the contact materials, a planarization process, such as a CMP process, may be then performed. In some embodiments, prior to the formation of the deep contact plugs 420, metal silicide layers SL4 are respectively formed in the contact openings and over the exposed backside of the source/drain epitaxial structures 260. The metal silicide layers SL4 may be formed by suitable deposition process and silicidation process. The metal silicide layers SL4 may include silicides of nickel, cobalt, titanium, tantalum, platinum, tungsten, other noble metals, other refractory metals, rare earth metals or their alloys. Other details of the present embodiments are similar to those mentioned above, and therefore not repeated herein.

A back-side multilayer interconnection (MLI) structure may be formed over the structure of FIGS. 18A and 18B. The back-side MLI structure may include a plurality of back-side metallization layers. The number of back-side metallization layers may vary according to design specifications of the integrated circuit. The back-side metallization layers each comprise a back-side inter-metal dielectric (IMD) layer, one or more horizontal interconnects, such as back-side metal lines, respectively extending horizontally or laterally in the back-side IMD layer, and vertical interconnects, such as back-side conductive vias, respectively extending vertically in the back-side IMD layer.

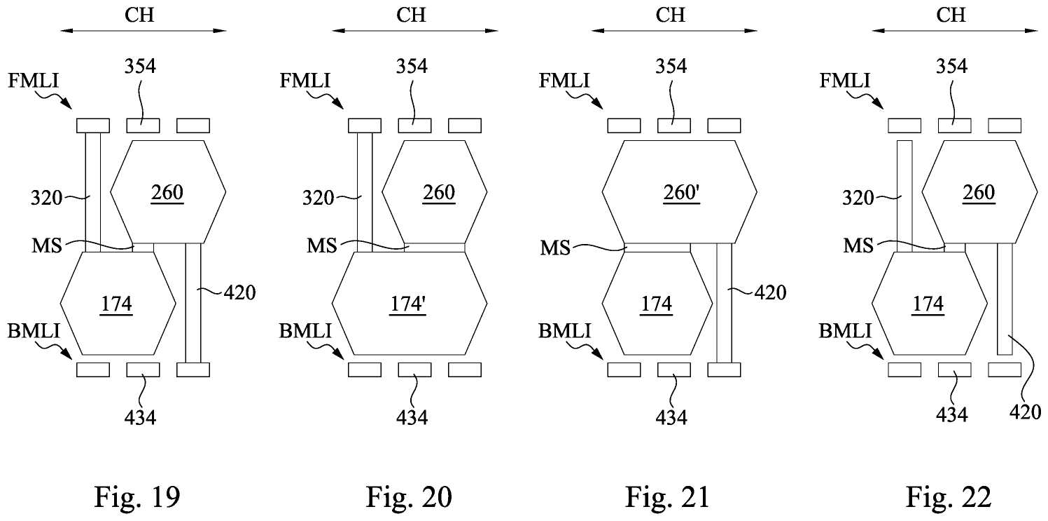

FIG. 19 is a schematic cross-sectional view of an integrated circuit device in accordance with some embodiments of the present disclosure. In the present embodiments, a source/drain epitaxial structure 260 of a transistor is stacked on a source/drain epitaxial structure 174 of another transistor. A frontside deep contact plug 320 lands on a frontside of the source/drain epitaxial structure 174 and may be electrically connected to metal lines 354 of the front-side MLI structure FMLI. A backside deep contact plug 420 lands on a backside of the source/drain epitaxial structure 260 and may be electrically connected to metal lines 434 of the back-side MLI structure BMLI. Centers of the source/drain epitaxial structures 174 and 260 are laterally offset from (or misaligned with) each other, thereby creating spaces for accommodating the frontside deep contact plug 320 and the backside deep contact plug 420. For example, a left sidewall of the source/drain epitaxial structure 174 extends beyond a left sidewall of the source/drain epitaxial structure 260, and a right sidewall of the source/drain epitaxial structure 260 extends beyond a left sidewall of the source/drain epitaxial structure 174. A cell height CH of the CFET including the two transistors is indicated in the figure. With the configuration of the frontside deep contact plug 320 and/or the backside deep contact plug 420, the configuration of deep via can be achieved with less cell height CH.

In some embodiments, a middle structure MS is between the source/drain epitaxial structures 174 and 260. In some embodiments, the middle structure MS is a dielectric structure electrically isolating the source/drain epitaxial structure 260 from the source/drain epitaxial structure 174. For example, the middle structure MS may include the dielectric layers 200 and 210, the ESL 182, and the ILD layer 184 (referring to FIGS. 2A-18B). In some embodiments, the middle structure MS is a conductive structure electrically connecting the source/drain epitaxial structure 260 to the source/drain epitaxial structure 174. For example, the middle structure MS may include the contact plugs 310′ (referring to FIGS. 2A-18B) that adjoins a sidewall of the source/drain epitaxial structure 260 and lands on the frontside of the source/drain epitaxial structure 174. Other details of the present embodiments are similar to those aforementioned, and thereto not repeated herein.

FIG. 20 is a schematic cross-sectional view of an integrated circuit device in accordance with some embodiments of the present disclosure. In the present embodiments, a source/drain epitaxial structure 260 of a transistor is stacked on a source/drain epitaxial structure 174′ of another transistor. A frontside deep contact plug 320 lands on a frontside of the source/drain epitaxial structure 174′ and may be electrically connected to metal lines 354 of the front-side MLI structure FMLI. In some embodiments, a size of the source/drain epitaxial structure 174′ may be greater than that of the source/drain epitaxial structure 260, thereby creating spaces for accommodating the frontside deep contact plug 320. For example, a left sidewall of the source/drain epitaxial structure 174′ extend beyond a left sidewall of the source/drain epitaxial structure 260. At least a portion of the source/drain epitaxial structure 174′ is not overlapping (non-overlapping) the source/drain epitaxial structure 260, and therefore is capable of receiving the frontside deep contact plug 320. Other details of the present embodiments are similar to those aforementioned, and thereto not repeated herein.

FIG. 21 is a schematic cross-sectional view of an integrated circuit device in accordance with some embodiments of the present disclosure. In the present embodiments, a source/drain epitaxial structure 260′ of a transistor is stacked on a source/drain epitaxial structure 174 of another transistor. A backside deep contact plug 420 lands on a backside of the source/drain epitaxial structure 260′ and may be electrically connected to metal lines 434 of the back-side MLI structure BMLI. In some embodiments, a size of the source/drain epitaxial structure 260′ may be greater than that of the source/drain epitaxial structure 174, thereby creating spaces for accommodating the frontside deep contact plug 420. For example, a right sidewall of the source/drain epitaxial structure 260′ extend beyond a right sidewall of the source/drain epitaxial structure 174. At least a portion of a bottom surface of the source/drain epitaxial structure 260′ is not overlapping(non-overlapping) the source/drain epitaxial structure 260, and therefore is capable of receiving the frontside deep contact plug 420. Other details of the present embodiments are similar to those aforementioned, and thereto not repeated herein.

FIG. 22 is a schematic cross-sectional view of an integrated circuit device in accordance with some embodiments of the present disclosure. Details of the present embodiments are similar to that of FIG. 19, except that the deep contact plug 320 is not in contact with the metal lines 354 of the front-side MLI structure FMLI, and the deep contact plug 420 is not in contact with the metal lines 434 of the back-side MLI structure BMLI. In some embodiments, some conductive features may be formed to laterally connect the deep contact plug 320/420 to target conductive features (e.g., metal lines 354 of the MLI structure FMLI/BMLI), and therefore there may be no vertical conductive feature between the metal lines 354/434 of the MLI structure FMLI/BMLI and the deep contact plug 320/420. Other details of the present embodiments are similar to those aforementioned, and thereto not repeated herein.

In the context, the deep contact plug 320/420 can also be referred to as shortened deep via or a metal-to-diffusion (MD) structure. In some embodiments, the deep contact plug 320/420 is applicable to provide some middle-end connectivity. For example, the deep contact plug 320/420 can be MD-flyer, in which an isolation layer is created between the deep contact plug 320/420 and the epitaxial structure 174/260, so that the deep contact plug 320/420 can be used for signal transmission. In some embodiments, the deep contact plug 320/420 can be a horizontal MD structure that laterally connects another epitaxial structure. In some embodiments, the deep contact plug 320/420 can be a drain jumper, in which a horizontal connection is created between two drain epitaxial structures 174/260 and across gate structures 190/280, etc.

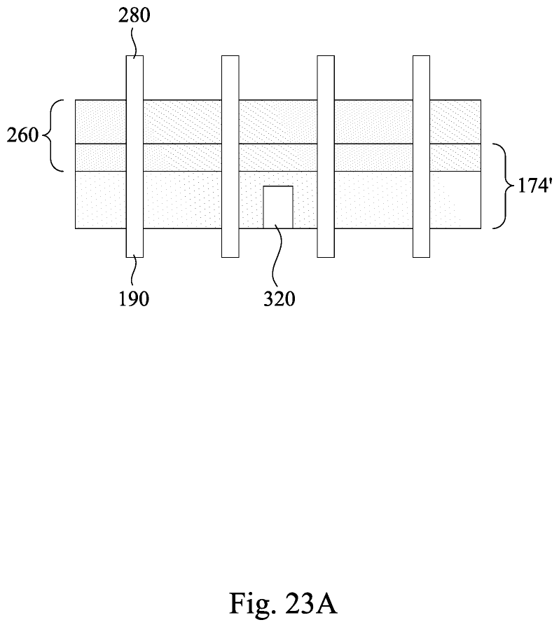

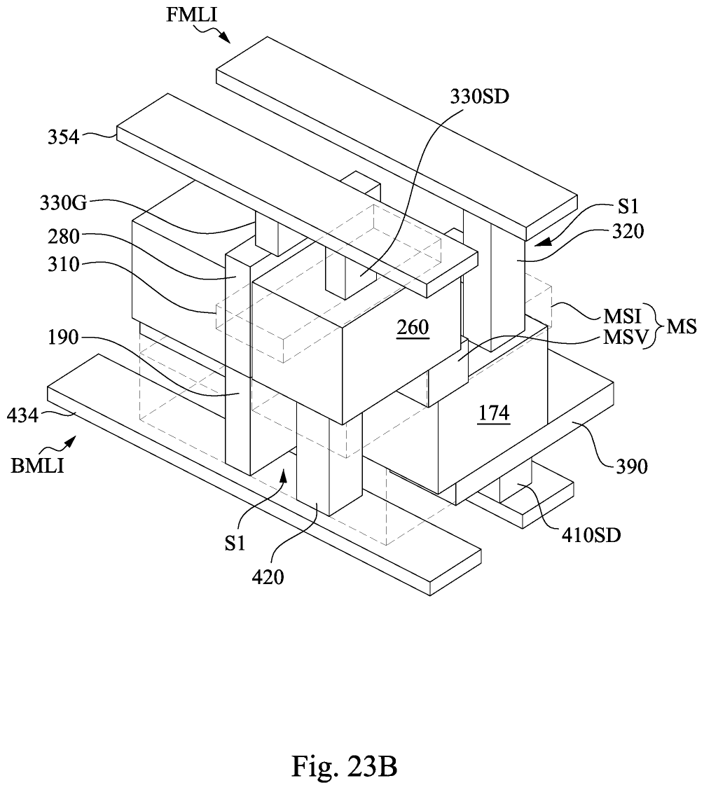

FIG. 23A is a schematic top view of an integrated circuit device in accordance with some embodiments of the present disclosure. FIG. 23B is a schematic view of an integrated circuit device in FIG. 23A. As the embodiments shown in FIG. 19, a source/drain epitaxial structure 260 of a transistor is stacked on a source/drain epitaxial structure 174 of another transistor. A frontside deep contact plug 320 lands on a frontside of the source/drain epitaxial structure 174 and may be electrically connected to metal lines 354 of the front-side MLI structure FMLI. A backside deep contact plug 420 lands on a backside of the source/drain epitaxial structure 260 and may be electrically connected to metal lines 434 of the back-side MLI structure BMLI. Centers of the source/drain epitaxial structures 174 and 260 are be laterally offset from (or misaligned with) each other, thereby creating spaces S1 and S2 for accommodating the frontside deep contact plug 320 and the backside deep contact plug 420.

In some embodiments, the middle structure MS between the source/drain epitaxial structures 174 and 260 include a dielectric portion MSI and a conductive portion MSV. The dielectric portion MSI may optionally include the dielectric layers 200 and 210, the ESL 182, and the ILD layer 184 (referring to FIGS. 2A-18B). The conductive portion MSV may include a portion of the contact plugs 310′ (referring to FIGS. 2A-18B) or other suitable conductive materials. In the present embodiments, the conductive portion MSV may electrically connect the source/drain epitaxial structures 174 and 260 to each other. In some alternative embodiments, the dielectric portion MSI may electrically isolate the source/drain epitaxial structures 174 and 260 from each other. The middle structure MS may also be located between the high-k/metal gate structures 190 and 280. In some embodiments, the conductive portion MSV may electrically connect the high-k/metal gate structures 190 and 280 to each other. In some alternative embodiments, the dielectric portion MSI may electrically isolate the high-k/metal gate structures 190 and 280 from each other.

The integrated circuit device may include a front-side contact plug 310 and a front-side conductive vias 330SD electrically connecting the source/drain epitaxial structure 260 to the front-side metal lines 354 in the front-side MLI structure FMLI. The integrated circuit device may include a back-side contact plug 390 and a conductive vias 410SD electrically connecting the source/drain epitaxial structure 174 to the back-side metal lines 434 in the back-side MLI structure BMLI. The integrated circuit device may include a front-side conductive vias 330G electrically connecting the gate structure 280 to the front-side metal lines 354 in the front-side MLI structure FMLI.

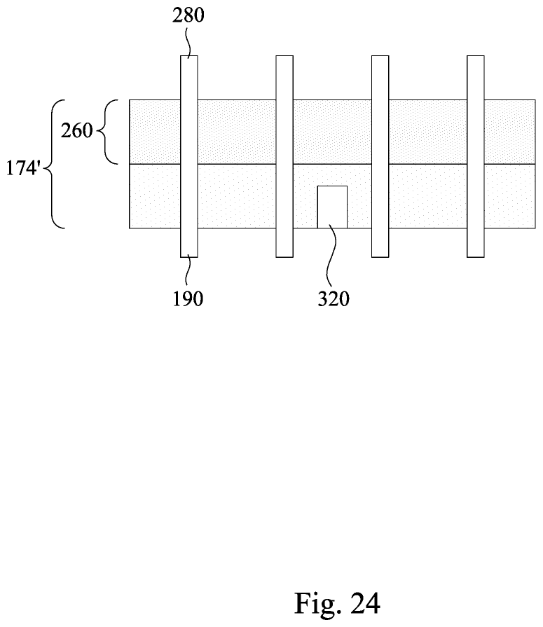

FIG. 24 is a schematic top view of an integrated circuit device in accordance with some embodiments of the present disclosure. As the embodiments shown in FIG. 20, the source/drain epitaxial structure 260 is stacked on the source/drain epitaxial structure 174′, and a size of the source/drain epitaxial structure 174′ may be greater than that of the source/drain epitaxial structure 260, thereby creating spaces for accommodating the frontside deep contact plug 320. For example, at least a portion of the source/drain epitaxial structure 174′ is not overlapped with the source/drain epitaxial structure 260, and therefore is capable of receiving the frontside deep contact plug 320. In some embodiments, a resistance from a bottom device to the front-side MLI structure FMLI is much larger than a resistance from top devices to the front-side MLI structure FMLI. Therefore, the epitaxial structure of the bottom device is enlarged to achieve balance n-type transistor and p-type transistors. Other details of the present embodiments are similar to those aforementioned, and thereto not repeated herein.

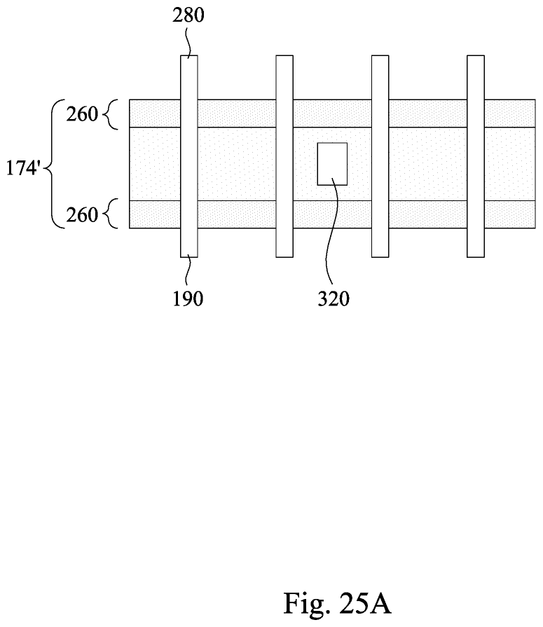

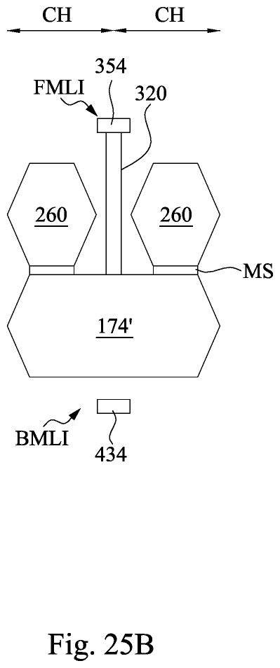

FIG. 25A is a schematic top view of an integrated circuit device in accordance with some embodiments of the present disclosure. FIG. 25B is a schematic cross-sectional view of the integrated circuit device in FIG. 25A. Details of the present embodiments are similar to that of FIG. 24, except that the source/drain epitaxial structures 174′ of two bottom transistors are merged to create even larger device currents. For example, two separate source/drain epitaxial structures 260 of two top transistors are stacked on a merged source/drain epitaxial structure 174′ of two bottom transistors. In the present embodiments, at least a middle portion of the source/drain epitaxial structure 174′ is not overlapped with the source/drain epitaxial structures 260, and therefore the middle portion of the source/drain epitaxial structure 174′ can receive the frontside deep contact plug 320. Other details of the present embodiments are similar to those aforementioned, and thereto not repeated herein.

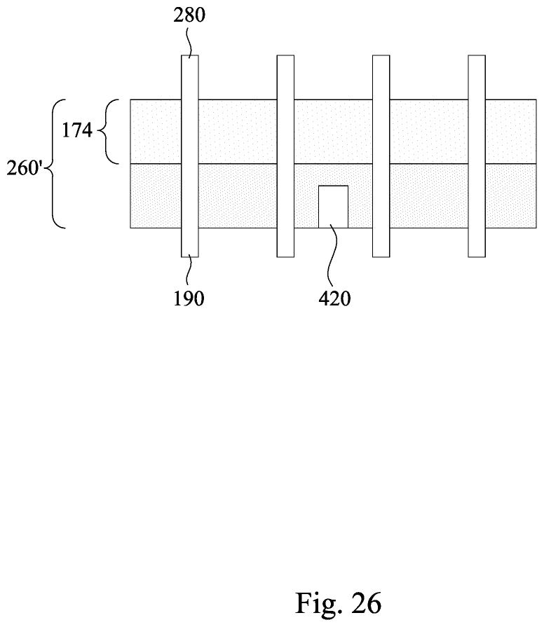

FIG. 26 is a schematic top view of an integrated circuit device in accordance with some embodiments of the present disclosure. As the embodiments shown in FIG. 21, the source/drain epitaxial structure 260′ is stacked on the source/drain epitaxial structure 174, and a size of the source/drain epitaxial structure 260′ may be greater than that of the source/drain epitaxial structure 174, thereby creating spaces for accommodating the backside deep contact plug 420. For example, at least a portion of the source/drain epitaxial structure 260′ is not overlapped with the source/drain epitaxial structure 174, and therefore is capable of receiving the backside deep contact plug 420. Other details of the present embodiments are similar to those aforementioned, and thereto not repeated herein.

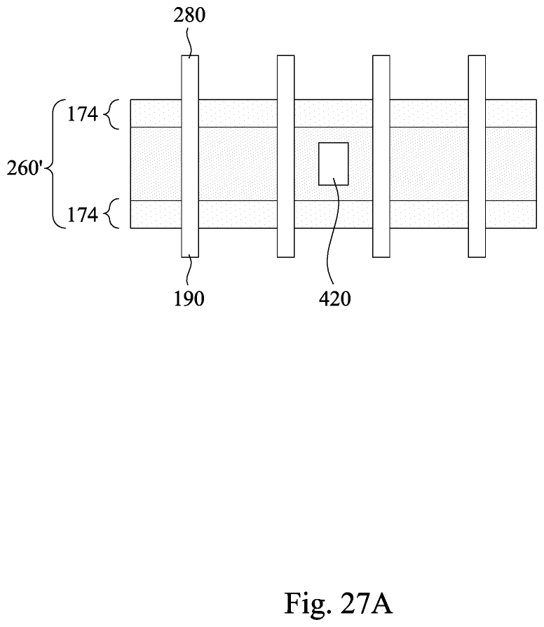

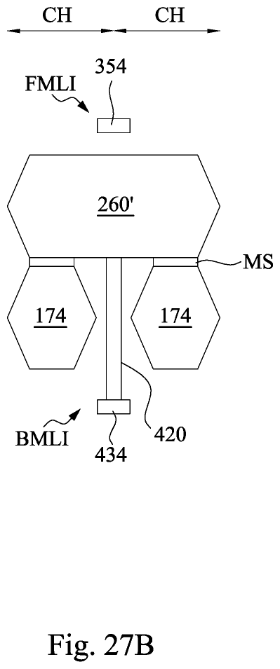

FIG. 27A is a schematic top view of an integrated circuit device in accordance with some embodiments of the present disclosure. FIG. 27B is a schematic cross-sectional view of the integrated circuit device in FIG. 27A. Details of the present embodiments are similar to that of FIG. 26, except that the source/drain epitaxial structures 260′ of top transistors are merged to create even larger device currents. For example, a merged source/drain epitaxial structure 260′ of two top transistors are stacked on two separate source/drain epitaxial structure 174 of two bottom transistors. In the present embodiments, at least a middle portion of the source/drain epitaxial structure 260′ is not overlapped with the source/drain epitaxial structures 174, and the middle portion of the source/drain epitaxial structure 260′ is capable of receiving the frontside deep contact plug 420. Other details of the present embodiments are similar to those aforementioned, and thereto not repeated herein.

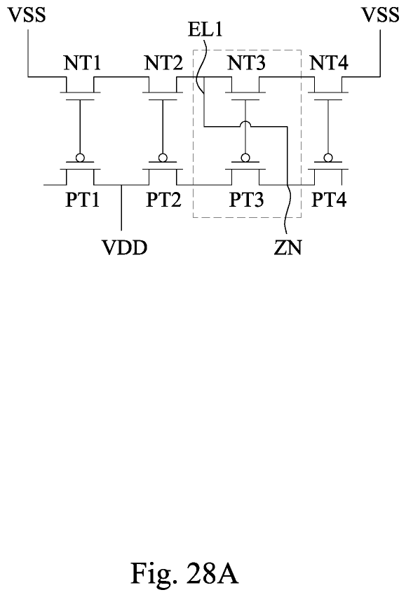

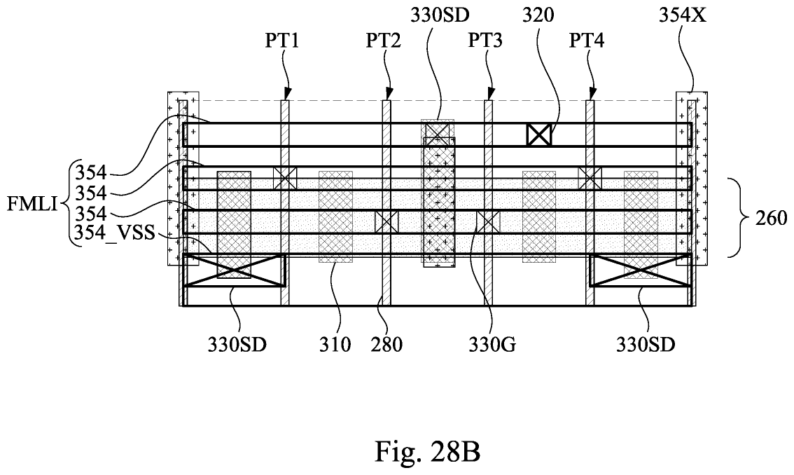

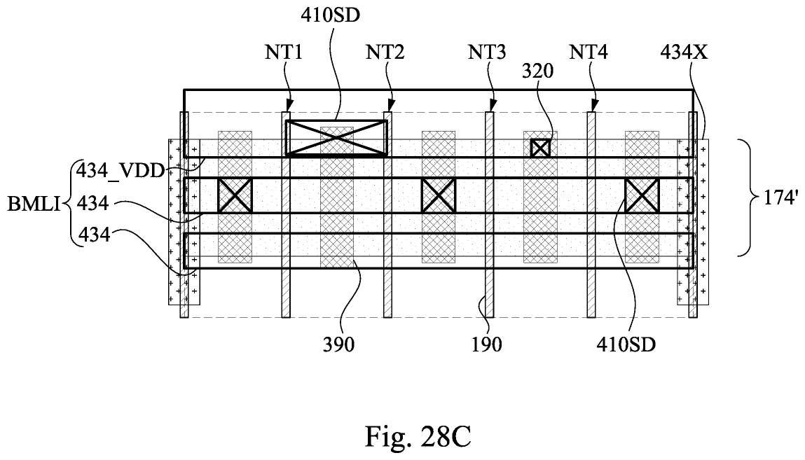

FIG. 28A is a circuit diagram of a AND-OR-INVERT-22 (AOI22) logic gate in accordance with some embodiments of the present disclosure. FIGS. 28B and 28C are layouts of the AOI logic gate of FIG. 28A in accordance with some embodiments of the present disclosure. FIG. 28B illustrates elements of n-type transistors NT1-NT4, such as the high-k/metal gate structure 280 and the source/drain epitaxial structures 260, the front-side MLI structure FMLI, the front-side conductive vias 330G and 330SD, and the frontside contact plugs 310. FIG. 28C illustrates elements of p-type transistors PT1-PT4, such as the high-k/metal gate structure 190 and the source/drain epitaxial structure 174′. the back-side MLI structure BMLI, the back-side conductive vias 410SD, and the backside contact plugs 390. As the embodiments shown in FIG. 20, the source/drain epitaxial structure 260 is stacked on the source/drain epitaxial structure 174′, and a size/width of the source/drain epitaxial structure 174′ may be greater than that of the source/drain epitaxial structure 260, thereby creating spaces for accommodating the frontside deep contact plug 320. For example, at least a portion of the source/drain epitaxial structure 174′ is not covered by the source/drain epitaxial structure 260, and therefore is capable of receiving the frontside deep contact plug 320.

In the present embodiments, one of the front-side metal lines 354 of the front-side MLI structure FMLI is electrically connected to a low voltage potential node VSS, such as being grounded, and said one of the front-side metal lines 354 is labelled as metal lines 354_VSS. Similarly, one of the back-side metal lines 434 of the back-side MLI structure BMLI is electrically connected to a high voltage potential node VDD, and said one of the back-side metal lines 434 is labelled as metal lines 434_VDD. The four n-type transistors NT1-NT4 respectively share gates with the four p-type transistors PT1-PT4. Through the frontside deep contact plug 320, a source/drain node (e.g., the source/drain epitaxial structure 174′) shared between the p-type transistor PT3 and PT4 is electrically connected to a front-side metal line 354, and then electrically connected to a source/drain node (e.g., the source/drain epitaxial structure 260) shared between the n-type transistor NT2 and NT3 by a contact plug 310 over the source/drain epitaxial structure 260 and a conductive vias 330SD connecting the contact plug 310 to the front-side metal line 354. This electrical connection is indicated by the electrical line EL1 in FIG. 28A. An output node ZN of the AOI22 logic gate is shown in the figure. Other details of the present embodiments are similar to those aforementioned, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a CFET device is fabricated with non-aligned source/drain epitaxial structures, thereby creating space for shortened deep via connected the frontside/backside metal. Another advantage is that the configuration of deep via can be achieved with less cell height by using the shortened deep via. Another advantage is that the shortened deep via extending from a front-side MLI structure to a frontside of an epitaxial structure of a bottom transistor is shorter than a via extending from a front-side MLI structure to a backside of an epitaxial structure of a transistor, which provides less process difficulty due to lower aspect ratio. Still another advantage is that the shortened deep via is applicable to middle-end connectivity. Still another advantage is that the non-aligned source/drain epitaxial structures with different sizes may compensate the difference of carrier mobility between n-type and p-type transistors, such that the CFET may have a greater effective current to be provided. Still another advantage is that the non-aligned source/drain epitaxial structures and the shortened deep via with less distance and smaller resistance may balance the performance between the n-type and p-type transistors, thereby increasing the effective current to be provided. Still another advantage is that the non-aligned source/drain epitaxial structures may be arranged based on logic cell design, for obtaining suitable currents in the logic cell.

According to some embodiments of the present disclosure, an integrated circuit device includes a first semiconductor layer, a second semiconductor layer, a first source/drain epitaxial structure, a second source/drain epitaxial structure, and a first contact plug. The second semiconductor layer is above the first semiconductor layer. The first and second semiconductor layers are vertically spaced apart from each other. The first source/drain epitaxial structure is on a side of the first semiconductor layer. The second source/drain epitaxial structure is on a side of the second semiconductor layer and above the first source/drain epitaxial structure. The first source/drain epitaxial structure has a portion non-overlapping the second source/drain epitaxial structure from a top view. The first contact plug is over a frontside of the first source/drain epitaxial structure. The first contact plug overlaps the portion of the first source/drain epitaxial structure from the top view.

According to some embodiments of the present disclosure, an integrated circuit device includes a first transistor and a second transistor. The first transistor includes a first semiconductor layer, a first gate structure surrounding the first semiconductor layer, and a first source/drain epitaxial structure on a side of the first semiconductor layer. The second transistor is stacked over the first transistor. The second transistor comprises a second semiconductor layer above the first semiconductor layer, a second gate structure surrounding the second semiconductor layer, and a second source/drain epitaxial structure on a side of the second semiconductor layer, wherein from a top view, the second source/drain epitaxial structure overlaps the first source/drain epitaxial structure, and a center of the second source/drain epitaxial structure is laterally offset from a center of the first source/drain epitaxial structure.

According to some embodiments of the present disclosure, a method includes forming a first transistor over a substrate, wherein the first transistor comprises a first semiconductor layer, a first gate structure surrounding the first semiconductor layer, and a first source/drain epitaxial structure on a side of the first semiconductor layer; forming a first interlayer dielectric layer around the first transistor; forming a second semiconductor layer over the first semiconductor layer and the first interlayer dielectric layer; forming a second gate structure over the second semiconductor layer; epitaxially growing a second source/drain epitaxial structure on a side of the second semiconductor layer, wherein from a top view, the second source/drain epitaxial structure overlaps the first source/drain epitaxial structure, and a center of the second source/drain epitaxial structure is laterally offset from a center of the first source/drain epitaxial structure; and forming a second interlayer dielectric layer around the second source/drain epitaxial structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first semiconductor layer and a second semiconductor layer above the first semiconductor layer, wherein the first and second semiconductor layers are vertically spaced apart from each other;
a first source/drain epitaxial structure on a side of the first semiconductor layer;
a second source/drain epitaxial structure on a side of the second semiconductor layer and above the first source/drain epitaxial structure, wherein the first source/drain epitaxial structure has a portion non-overlapping the second source/drain epitaxial structure from a top view; and
a first contact plug over a frontside of the first source/drain epitaxial structure, wherein the first contact plug overlaps the portion of the first source/drain epitaxial structure from the top view.

2. The integrated circuit device of claim 1, wherein the first source/drain epitaxial structure and the second source/drain epitaxial structure are of opposite conductive types.

3. The integrated circuit device of claim 1, wherein a width of the first source/drain epitaxial structure is greater than a width of the second source/drain epitaxial structure.

4. The integrated circuit device of claim 1, wherein a center of the first source/drain epitaxial structure is laterally offset from a center of the second source/drain epitaxial structure.

5. The integrated circuit device of claim 1, further comprising:
a first interlayer dielectric layer surrounding the second source/drain epitaxial structure, wherein the first contact plug extends in the first interlayer dielectric layer downward to the portion of the first source/drain epitaxial structure.

6. The integrated circuit device of claim 5, wherein the first contact plug is spaced apart from the second source/drain epitaxial structure by the first interlayer dielectric layer.

7. The integrated circuit device of claim 1, further comprising:
a second contact plug over a backside of the second source/drain epitaxial structure, wherein the second source/drain epitaxial structure has a portion non-overlapping the first source/drain epitaxial structure from the top view, and the second contact plug overlaps the portion of the second source/drain epitaxial structure from the top view.

8. The integrated circuit device of claim 7, further comprising:
a second interlayer dielectric layer surrounding the first source/drain epitaxial structure, wherein the second contact plug extends in the second interlayer dielectric upward to the portion of the second source/drain epitaxial structure.

9. The integrated circuit device of claim 8, wherein the second contact plug is spaced apart from the first source/drain epitaxial structure by the second interlayer dielectric layer.

10. An integrated circuit device, comprising:
a first transistor comprising a first semiconductor layer, a first gate structure surrounding the first semiconductor layer, and a first source/drain epitaxial structure on a side of the first semiconductor layer; and
a second transistor stacked over the first transistor, wherein the second transistor comprises a second semiconductor layer above the first semiconductor layer, a second gate structure surrounding the second semiconductor layer, and a second source/drain epitaxial structure on a side of the second semiconductor layer, wherein from a top view, the second source/drain epitaxial structure overlaps the first source/drain epitaxial structure, and a center of the second source/drain epitaxial structure is laterally offset from a center of the first source/drain epitaxial structure.

11. The integrated circuit device of claim 10, wherein the second source/drain epitaxial structure is electrically isolated from the first source/drain epitaxial structure.

12. The integrated circuit device of claim 10, further comprising:
a first contact plug over a frontside of the first source/drain epitaxial structure, wherein the first contact plug is spaced apart from the second source/drain epitaxial structure.

13. The integrated circuit device of claim 12, further comprising:
a second contact plug over a frontside of the second source/drain epitaxial structure, wherein a height of the first contact plug is greater than a height of the second contact plug.

14. The integrated circuit device of claim 10, further comprising:
a third contact plug over a backside of the second source/drain epitaxial structure, wherein the third contact plug is spaced apart from the first source/drain epitaxial structure.

15. The integrated circuit device of claim 14, further comprising:
a fourth contact plug over a backside of the first source/drain epitaxial structure, wherein a height of the third contact plug is greater than a height of the fourth contact plug.

16. A method, comprising:
forming a first transistor over a substrate, wherein the first transistor comprises a first semiconductor layer, a first gate structure over the first semiconductor layer, and a first source/drain epitaxial structure on a side of the first semiconductor layer;
forming a first interlayer dielectric layer around the first transistor;
stacking a second semiconductor layer over the first semiconductor layer;
forming a second gate structure over the second semiconductor layer; and
epitaxially growing a second source/drain epitaxial structure on a side of the second semiconductor layer, wherein from a top view, the second source/drain epitaxial structure overlaps the first source/drain epitaxial structure, and a center of the second source/drain epitaxial structure is laterally offset from a center of the first source/drain epitaxial structure; and
forming a second interlayer dielectric layer around the second source/drain epitaxial structure.

17. The method of claim 16, further comprising:
forming a first contact plug over a frontside of the first source/drain epitaxial structure, wherein the first contact plug extends though the first and second interlayer dielectric layers.

18. The method of claim 16, further comprising:
forming a second contact plug over a backside of the second source/drain epitaxial structure, wherein the second contact plug extends though the first and second interlayer dielectric layers.

19. The method of claim 16, wherein stacking the second semiconductor layer over the first semiconductor layer comprises:
forming a first dielectric layer over the first transistor;
forming a second dielectric layer over the second semiconductor layer; and
bonding the first dielectric layer to the second dielectric layer.

20. The method of claim 16, wherein epitaxially growing the second source/drain epitaxial structure is performed such that a width of the second source/drain epitaxial structure is different from a width of the first source/drain epitaxial structure.
